(19) United States
(12) Patent Application Publication
(10) Pub. No.: US 2024/0222205 A1
(43) Pub. Date: Jul. 4, 2024

(54) SEMICONDUCTOR DEVICE INCLUDING CRACK DETECTION STRUCTURE AND METHOD OF DETECTING PROGRESSIVE CRACK IN SEMICONDUCTOR DEVICE

(71) Applicant: Samsung Electronics Co., Ltd., Suwon-si (KR)

(72) Inventors: Chulhee JEON, Suwon-si (KR); Sungho PARK, Suwon-si (KR); Younggu KANG, Suwon-si (KR); Inho LIM, Suwon-si (KR)

(73) Assignee: Samsung Electronics Co., Ltd., Suwon-si (KR)

(21) Appl. No.: 18/341,818

(22) Filed: Jun. 27, 2023

(30) Foreign Application Priority Data
Dec. 28, 2022 (KR) 10-2022-0186658

(51) Int. Cl. H01L 21/66; G01R 31/28; H01L 23/58

(52) U.S. Cl. CPC H01L 22/34; G01R 31/2896; H01L 23/585

(57) ABSTRACT

A semiconductor device includes a semiconductor die, a chip guard ring, a first crack detection structure, a second crack detection structure and a detection controller. The semiconductor die includes a central region in which a semiconductor integrated circuit is arranged and an external region surrounding the central region. The semiconductor device may accelerate a progress of a crack occurring around the first crack detection structure by applying a first power and a second power having a voltage level difference to the first crack detection structure and the second crack detection structure, respectively, in a first phase, may apply a test input signal to the first crack detection structure in a second phase and may determine whether a progressive crack occurs in the central region based on whether a test output signal responding to the test input signal is detected in the second crack detection structure, in the second phase.

### CROSS-REFERENCE TO RELATED APPLICATION

This US application claims the benefit of priority under 35 USC § 119 to Korean Patent Application No. 10-2022-0186658, field on Dec. 28, 2022, in the Korean Intellectual Property Office, the disclosure of which is incorporated by reference herein in its entirety.

### BACKGROUND

Various example embodiments generally relate to semiconductor integrated circuits, and more particularly to a semiconductor device including a detection structure and/or a method of detecting a progressive crack in a semiconductor device, and/or a method of downgrading semiconductor devices which may lead to an improved yield and/or reliability.

In general, integrated circuits are manufactured by forming repeated patterns on a wafer of semiconductor material. Progressive cracks due to seams on a profile according to etching process during forming patters may not be detected. It is required or desired to prevent or reduce the likelihood of the shipment of defective products by more accurately detecting such progressive cracks.

### SUMMARY

Some example embodiments may provide a semiconductor device including a crack detection structure capable of detecting progressive cracks by accelerating progress of cracks.

Alternatively or additionally, some example embodiments may provide a method of detecting a progressive crack in a semiconductor device.

According to various example embodiments, a semiconductor device includes a semiconductor die, a chip guard ring, a first crack detection structure, a second crack detection structure, and a detection controller. The semiconductor die includes a central region in which a semiconductor integrated circuit is arranged and an external region surrounding the central region. The chip guard ring is arranged inside the semiconductor die along an edge of the semiconductor die and separates the central region and the external region. The first crack detection structure is arranged along an edge of the central region as a closed curve. The second crack detection structure is arranged along the edge of the central region as a closed curve, and is spaced apart from the chip guard ring farther than the first crack detection structure. In a first phase, the detection controller is configured to induce an electrical short circuit between the first crack detection structure and the second crack detection structure by applying a first power to the first crack detection structure and by applying a second power greater than the first power to the second crack detection structure. In a second phase, the detection controller is configured to apply a test input signal to the first crack detection structure, and to determine whether a progressive crack occurs in the central region based on whether a test output signal responding to the test input signal is detected in the second crack detection structure in the second phase.

Alternatively or additionally according to some example embodiments, there is provided a method of detecting a progressive crack in a semiconductor device which includes a semiconductor die including a central region in which a semiconductor integrated circuit is arranged and an external region surrounding the central region and a chip guard ring arrange inside the semiconductor die along an edge of the semiconductor die so as to separate the central region and the external region. According to the method, a first power and a second power greater than the first power are applied to a first crack detection structure and a second crack detection structure, respectively, during a first time interval in a first phase, where the first crack detection structure is arranged along an edge of the central region as a closed curve, the second crack detection structure is arranged along the edge of the central region as a closed curve and the second crack detection structure is spaced apart from the chip guard ring farther than the first crack detection structure, a test input signal is applied to the first crack detection structure during a second time interval in a second phase, and a progressive crack may be determined to occur in the central region based on whether a test output signal responding to the test input signal is detected in the second crack detection structure in the second phase.

Alternatively or additionally according to some example embodiments, a semiconductor device includes a semiconductor die, a chip guard ring, a crack detection structure and a detection controller. The semiconductor die includes a central region in which a semiconductor integrated circuit is arranged and an external region surrounding the central region. The chip guard ring is arranged inside the semiconductor die along an edge of the semiconductor die and separates the central region and the external region. The crack detection structure is arranged along an edge of the central region as a closed curve. The detection controller is configured to induce an electrical short circuit between the crack detection structure and the chip guard ring by applying a power to the crack detection structure during a first time interval in a first phase, to apply a test input signal to the crack detection structure in a second phase, and to determine whether a progressive crack occurs in the central region based on whether a test output signal responding to the test input signal is detected in the crack detection structure in the second phase.

Therefore, the semiconductor device according to various example embodiments may accelerate a progress of a crack occurring around the first crack detection structure by applying a first power and a second power having a voltage level difference to the first crack detection structure and the second crack detection structure, respectively, in the first phase, may apply a pulse signal and/or a DC voltage to the first crack detection structure in a second phase, and may determine whether a progressive crack occurs in the central region based on whether the pulse signal or the DC voltage is detected in the second crack detection structure, in the second phase. Therefore, the semiconductor device according to various example embodiments may be screened and may be removed from further processing or downgraded when having potential defects, and thus yield and/or reliability of the semiconductor device may be enhanced.

### BRIEF DESCRIPTION OF THE DRAWINGS

Various example embodiments will be described below in more detail with reference to the accompanying drawings.

FIG. 1 is a top view illustrating a layout of a semiconductor device according to some example embodiments.

FIG. 2 is a cross-sectional view taken along line I-I′ of the semiconductor device of FIG. 1 according to some example embodiments.

FIG. 3 are cross-sectional views taken along lines II-II′ and III-III′ of the semiconductor device of FIG. 1 according to some example embodiments.

FIG. 4 illustrates a portion of the semiconductor device of FIG. 1 according to some example embodiments.

FIG. 5A illustrates a portion in the semiconductor device of FIG. 4 before a first power and a second power are applied to the first crack detection structure and the second crack detection structure, respectively.

FIG. 5B illustrates a portion in the semiconductor device of FIG. 4 before a first power and a second power are applied to the first crack detection structure and the second crack detection structure, respectively.

FIG. 6 illustrates an example that a first power and a second power are applied to the first crack detection structure and the second crack detection structure, respectively, in the semiconductor device of FIG. 1.

FIG. 7 illustrates an example that a first power and a second power are applied to the first crack detection structure and the second crack detection structure, respectively, in the semiconductor device of FIG. 1.

FIG. 8 illustrates signals that are applied to and/or output from the semiconductor device of FIG. 1 in a second phase.

FIG. 9 is a timing diagram illustrating an example operation of the detection controller in FIG. 8 according to some example embodiments.

FIG. 10 is a perspective view illustrating an example of a first crack detection structure according to some example embodiments.

FIG. 11 is a perspective view illustrating an example of a second crack detection structure according to some example embodiments.

FIGS. 12 and 14 are cross-sectional diagrams illustrating a vertical structure of a first crack detection structure according to some example embodiments.

FIGS. 13 and 15 are cross-sectional diagrams illustrating a vertical structure of a second crack detection structure according to some example embodiments.

FIGS. 16, 17, and 18 illustrate examples that a first power and a second power are applied to the first crack detection structure and the second crack detection structure, respectively, in the semiconductor device of FIG. 1.

FIG. 19 illustrates the semiconductor device of FIG. 1 according to some example embodiments.

FIG. 20 illustrates an example of the second switch circuit in the semiconductor device of FIG. 19 according to some example embodiments.

FIG. 21 is a top view illustrating a layout of a semiconductor device according to some example embodiments.

FIG. 22 is a cross-sectional view taken along line IV-IV′ of the semiconductor device of FIG. 21 according to some example embodiments.

FIG. 23 is a cross-sectional view taken along line V-V′ of the semiconductor device of FIG. 21 according to some example embodiments.

FIG. 24 illustrates the semiconductor device of FIG. 21 according to some example embodiments.

FIG. 25 is a flow chart illustrating a method of detecting a progressive crack in a semiconductor device according to some example embodiments.

FIG. 26 is a block diagram illustrating a semiconductor device according to some example embodiments.

FIG. 27 schematically illustrates a structure of the nonvolatile memory device of FIG. 26 according to some example embodiments.

FIG. 28 is a block diagram illustrating an example of the memory cell array in FIG. 26 according to some example embodiments.

FIG. 29 is a circuit diagram illustrating one of the memory blocks of FIG. 28 according to some example embodiments.

FIG. 30 is a block diagram illustrating an example of the semiconductor device in FIG. 1 according to some example embodiments.

FIG. 31 illustrates an example of the first bank array in the semiconductor device of FIG. 30.

FIG. 32 is a plan view for explaining a semiconductor device according to some example embodiments.

### DETAILED DESCRIPTION OF VARIOUS EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

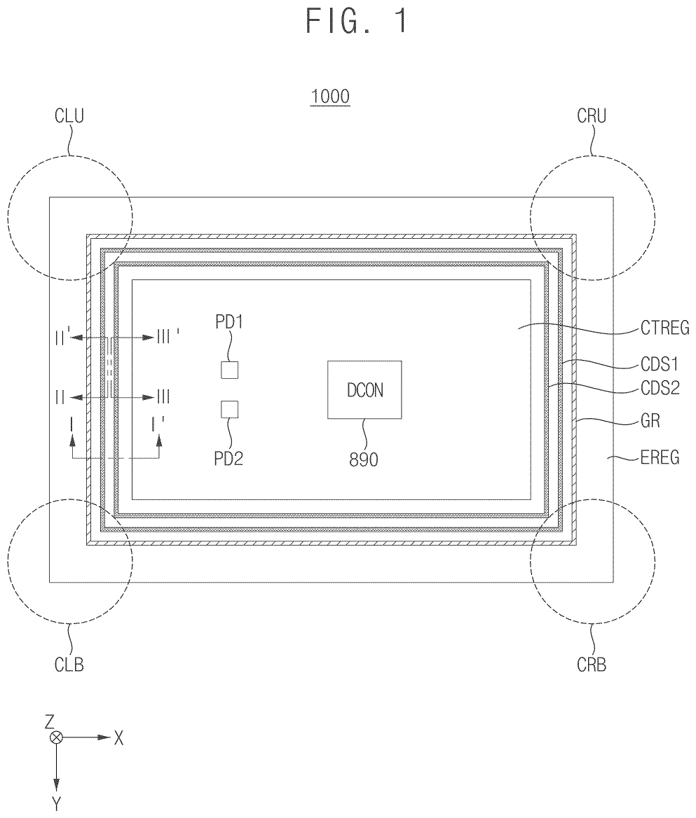

FIG. 1 is a top view illustrating a layout of a semiconductor device according to some example embodiments.

Referring to FIG. 1, a semiconductor device 1000 may include at least one semiconductor die. The semiconductor die may include a central region CTREG and an external region EREG surrounding the central region CTREG. The semiconductor device 1000 may include a chip guard ring GR, a first crack detection structure CDS1, and a second crack detection structure CDS2.

Various semiconductor integrated circuits may be formed or arranged in the central region CTREG, depending on a kind and/or type of the semiconductor device 1000. For example, the semiconductor device 1000 may be or may include or be included in a nonvolatile memory device, and a memory integrated circuit may be formed in the central region CTREG of the semiconductor die.

The external region EREG may be a region in which no element is formed or a region in which only dummy elements, e.g. elements that are not electrically active or operational, are formed. The external region EREG may be a place having a space margin, for example in case of a damaged part when dicing the wafer so as to singulate the semiconductor device 1000.

Even if a crack, e.g., a cracking phenomenon of the semiconductor device 1000 occurs in the external region EREG, there may not be a problem in the direct operation of the semiconductor device 1000. However, when cracks occur in the central region CTREG of the semiconductor device 1000 or cracks proceed from the external region EREG to the central region CTREG, the reliability of the operation of the semiconductor device 1000 may be greatly impaired.

The chip guard ring GR may be formed inside the semiconductor die along an edge of the semiconductor die so as to separate the central region CTREG and the external region EREG. The chip guard ring GR may be located between the central region CTREG and the external region EREG. The chip guard ring GR may serve to block or at least partly block or inhibit progress of the above-described cracks from the external region EREG to the central region CTREG.

Alternatively or additionally, the chip guard ring GR may perform a moisture absorption action which prevents or reduces an amount of external moisture from entering the inside of the semiconductor device 1000. For example, when moisture enters the central region CTREG of the semiconductor device 1000, the elements located in the central region CTREG of the semiconductor device 1000 may be damaged and/or malfunction. The chip guard ring GR may prevent or reduce the likelihood of such problems.

The chip guard ring GR may be formed while making a closed curve along the edge of the semiconductor die. Here, a “closed curve” refer to ring shapes that are in contact with one another, but does not necessarily indicate that the extended portion of the chip guard ring GR necessarily has curvature. For example, the horizontal arrangement shape of the chip guard ring GR be a polygon such as a rectangle or square, rather than a circle or an ellipse. In some example embodiments, a polygon as opposed to a circle or an ellipse, such as a polygonal guard ring GR and/or a polygonal first crack detection structure CDS1 and/or a polygonal second crack detection structure CDS2 may be easier to fabricate, but examples are not limited thereto.

The first crack detection structure CDS1 may be arranged along an edge of the central region CTREG in a form of a closed curve. The second crack detection structure CDS2 may be formed along the edge of the central region in a form of a closed curve, and the second crack detection structure CDS2 may be spaced apart from the chip guard ring GR farther than the first crack detection structure CDS1.

The semiconductor device 1000 may further include pads PD1 and PD2 and a detection controller DCON 890. The pads PD1 and PD2 are not necessarily arranged as in FIG. 1; for example, the pads PD1 and PD2 may not be arranged parallel to either the length axis or the width axis of the semiconductor device 1000.

The detection controller 890 may induce an electrical short circuit between the first crack detection structure CDS1 and the second crack detection structure CDS2 by applying a first power (e.g. a first voltage and/or a first current) to the first crack detection structure CDS1 and by applying a second power (e.g. a second voltage and/or a second current) having a level higher than a level of the first power to the second crack detection structure CDS2, in a first phase, may apply a test input signal (e.g. a test input voltage) to the first crack detection structure CDS1 in a second phase, and may determine whether a progressive crack occurs in the central region CTREG based on whether a test output signal responding to the test input signal is detected in the second crack detection structure CDS2. When the electrical short circuit is induced between the first crack detection structure CDS1 and the second crack detection structure CDS2, a progression of a crack occurring around the chip guard ring GR may be accelerated and the crack may proceed to the second crack detection structure CDS2. In some example embodiments, the detection controller 890 may induce an electrical short circuit after fabrication or after dicing of the semiconductor device; however, example embodiments are not necessarily limited thereto.

The pads PD1 and PD2 may be selectively used when applying the first power to the first crack detection structure CDS1, applying the second power to the second crack detection structure CDS2, and applying the test input signal to the first crack detection structure CDS1.

Each of the chip guard ring GR, the first crack detection structure CDS1, and the second crack detection structure CDS2 may include a first conduction segment passing through a left-bottom corner region CLB of the external region EREG, a second conduction segment passing through a left-upper corner region CLU of the external region EREG, a third conduction segment passing through a right-upper corner region CRU of the external region EREG, and a fourth conduction segment passing through a right-bottom corner region CRB of the external region EREG.

Each of the chip guard ring GR, the first crack detection structure CDS1 and the second crack detection structure CDS2 may be formed or arranged in a first direction, a second direction and a third direction.

Hereinafter, various example embodiments are described using an orthogonal set of an X direction, a Y direction and a Z direction for convenience of illustration and description. The X direction, the Y direction, and the Z direction refer to three perpendicular directions along the three directions, and are not limited to particular directions. The X direction corresponds to a first direction (e.g., a row direction), the Y direction corresponds to a second direction (e.g., a column direction) and the Z direction corresponds to a third direction or a vertical direction.

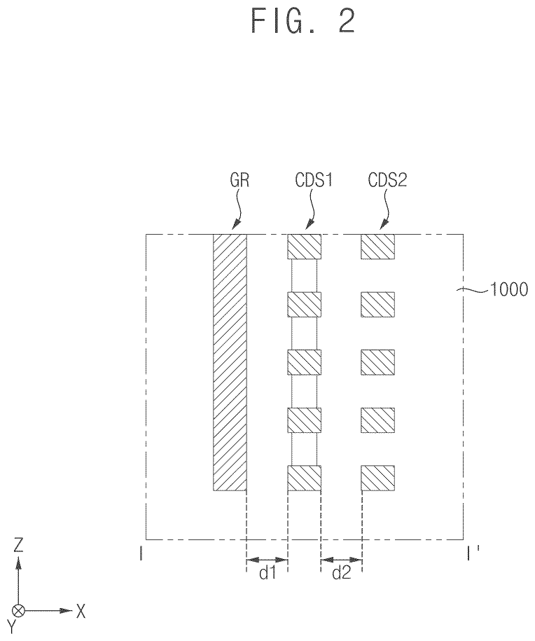

FIG. 2 is a cross-sectional view taken along line I-I′ of the semiconductor device of FIG. 1 according to some example embodiments.

Referring to FIG. 2, each of the chip guard ring GR, the first crack detection structure CDS1 and the second crack detection structure CDS2 may extend in the third direction Z.

The first crack detection structure CDS1 may be spaced apart from the chip guard ring GR by a first gap d1 in the first direction X and the second crack detection structure CDS2 may be may be spaced apart from the first crack detection structure CDS1 by a second gap d2 in the first direction X. Therefore, the second crack detection structure CDS2 may be may be spaced apart from the chip guard ring GR by a gap of greater than or equal to d1+d2 in the first direction X, and the second crack detection structure CDS2 may be may be spaced apart from the chip guard ring GR farther than the first crack detection structure CDS1.

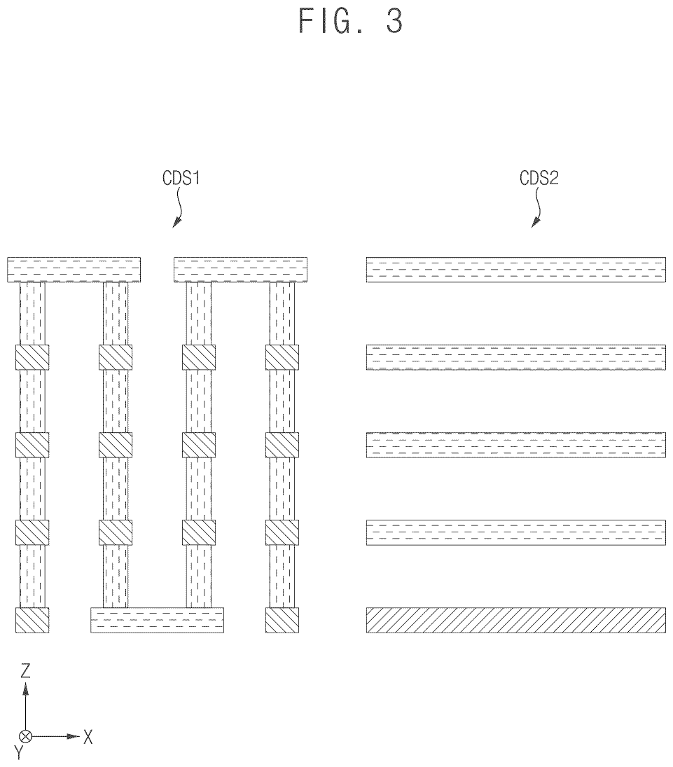

FIG. 3 are cross-sectional views taken along lines II-II′ and III-III′ of the semiconductor device of FIG. 1 according to some example embodiments.

Referring to FIG. 3, the first crack detection structure CDS1 may include a plurality of horizontal lines extending in the first direction X or in the second direction Y and a plurality of vertical lines that connect each of the plurality of horizontal lines in the third direction Z. The second crack detection structure CDS2 may include a plurality of horizontal lines extending in the first direction X or in the second direction Y. Each of the plurality of horizontal lines in the second crack detection structure CDS2 may constitute or correspond to a horizontal conduction loop.

Although five horizontal lines are illustrated in FIG. 3, example embodiments are not limited thereto, and the number of horizontal lines may be more than or less than five. Additionally or alternatively, a thickness of and/or an interlayer spacing between each horizontal line may be the same, or different from each other; example embodiments are not limited thereto.

Because the first crack detection structure CDS1 and the second crack detection structure CDS2 have structures as illustrated in FIG. 3, the first crack detection structure CDS1 may constitute a conduction loop and the second crack detection structure CDS2 may constitute a plurality of separated conduction loops. When a first power such as a first voltage is applied to the first crack detection structure CDS1 and the second power having a level such as a voltage level greater than a level of the first power is applied to the second crack detection structure CDS2, an electric field may be generated from the second crack detection structure CDS2 to the first crack detection structure CDS1. When the electric field is generated, electrons may move from the first crack detection structure CDS1 to the second crack detection structure CDS2 along a reverse direction of the electric field, an electrical short circuit may be induced between the first crack detection structure CDS1 and the second crack detection structure CDS2 due to a crack and/or a delamination occurring around the first crack detection structure CDS1, and the first crack detection structure CDS1 may be connected to or shorted to at least a portion of the second crack detection structure CDS2.

When the first crack detection structure CDS1 is connected to at least a portion of the second crack detection structure CDS2, a test output signal responding to a test input signal that is applied to the first crack detection structure CDS1 may be detected in the second crack detection structure CDS2.

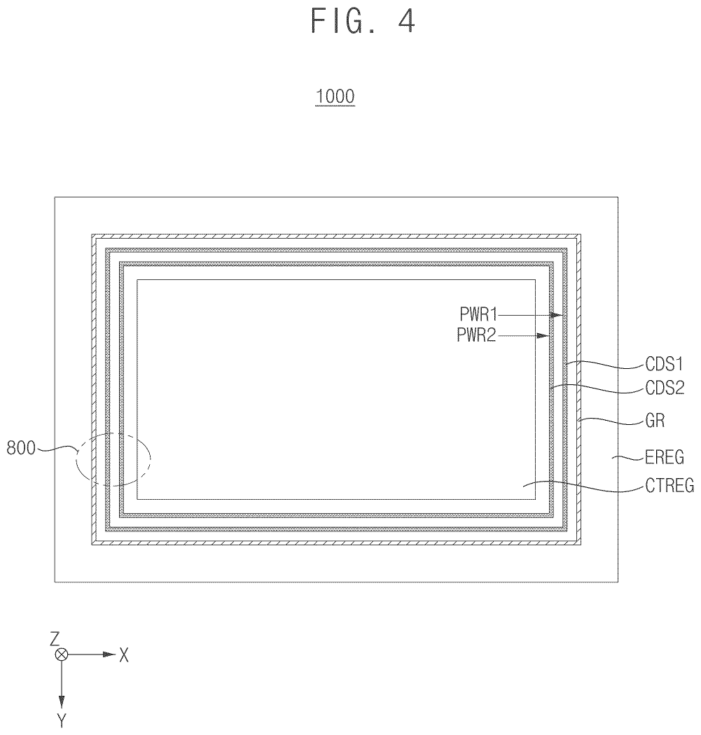

FIG. 4 illustrates a portion of the semiconductor device of FIG. 1 according to some example embodiments.

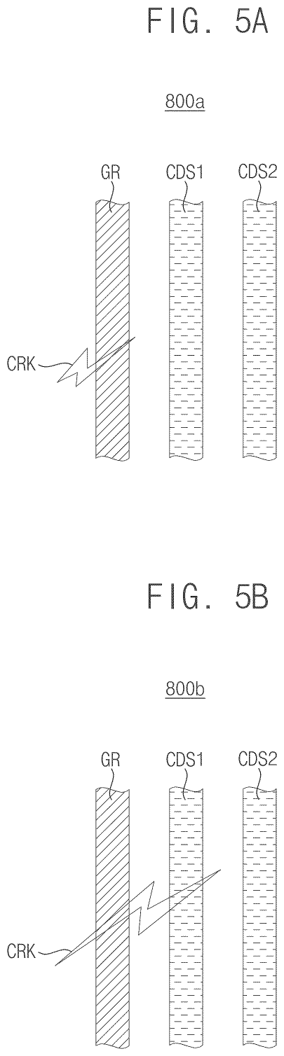

In FIG. 4, the chip guard ring GR, the first crack detection structure CDS1, and the second crack detection structure CDS2 are illustrated and a portion 800 of the first crack detection structure CDS1 and the second crack detection structure CDS2 will be described with reference to FIGS. 5A and 5B.

A first power PWR1 and a second power PWR2 having a level such as a voltage level higher than a voltage level of the first power PWR1 may be applied to the first crack detection structure CDS1 and the second crack detection structure CDS2, respectively. The second power PWR2 may have a voltage level with a value or an absolute value large enough for generating an electric field from the second crack detection structure CDS2 to the first crack detection structure CDS1, with respect to the voltage level of the first power PWR1. For example, a voltage difference between the second power PWR2 and the first power PWR1 may be one volt or two volts, or a value between one volt and two volts, however, example embodiments are not limited thereto.

When the first power PWR1 and the second power PWR2 are applied to the first crack detection structure CDS1 and the second crack detection structure CDS2, respectively, an electric field may be generated from the second crack detection structure CDS2 to the first crack detection structure CDS1. When the electric field is generated, electrons may move from the first crack detection structure CDS1 to the second crack detection structure CDS2 along a reverse direction of the electric field, an electrical short circuit is induced between the first crack detection structure CDS1 and the second crack detection structure CDS2 due to a crack or a delamination occurring around the first crack detection structure CDS1, and the first crack detection structure CDS1 is connected to or shorted to at least a portion of the second crack detection structure CDS2.

FIG. 5A illustrates a portion in the semiconductor device of FIG. 4 before a first power and a second power are applied to the first crack detection structure and the second crack detection structure, respectively.

Referring to FIGS. 4 and 5A, it is noted for illustrative purposes that a crack CRK occurring in the external region EREG in a portion 800a of the semiconductor device 1000 has proceeded to the chip guard ring GR. Because the crack CRK occurring in the external region EREG has progressed to the chip guard ring GR but has not progressed to the first crack detection structure CDS1, it may be determined that a crack does not occur in the portion 800a through a conventional crack detection scheme, and a semiconductor device including the portion 800a may be shipped inadvertently as a good product, and thus, the crack CRK may proceed through the second crack detection structure CDS2 during a client using the semiconductor device including the portion 800a. This may be detrimental to the reliability of the semiconductor device.

FIG. 5B illustrates a portion in the semiconductor device of FIG. 4 before a first power and a second power are applied to the first crack detection structure and the second crack detection structure, respectively.

Referring to FIGS. 4, 5A and 5B, when the first power PWR1 and the second power PWR2 are applied to the first crack detection structure CDS1 and the second crack detection structure CDS2, respectively, in a case in which the crack CRK occurring in the external region EREG in a portion 800b of the semiconductor device 1000 has proceeded to the first crack detection structure CDS1, an electric field is generated from the second crack detection structure CDS2 to the first crack detection structure CDS1. When the electric field is generated, electrons move from the first crack detection structure CDS1 to the second crack detection structure CDS2 along a reverse direction of the electric field, and thus a progress of the crack CRK is accelerated due to moving of the electrons. Therefore, a semiconductor device including the portion 800b may be screened and discarded as a defective product or downgraded as a lower quality product by a detecting scheme according to some example embodiments. Accordingly there may be an improvement in the overall yield and/or reliability of the semiconductor device.

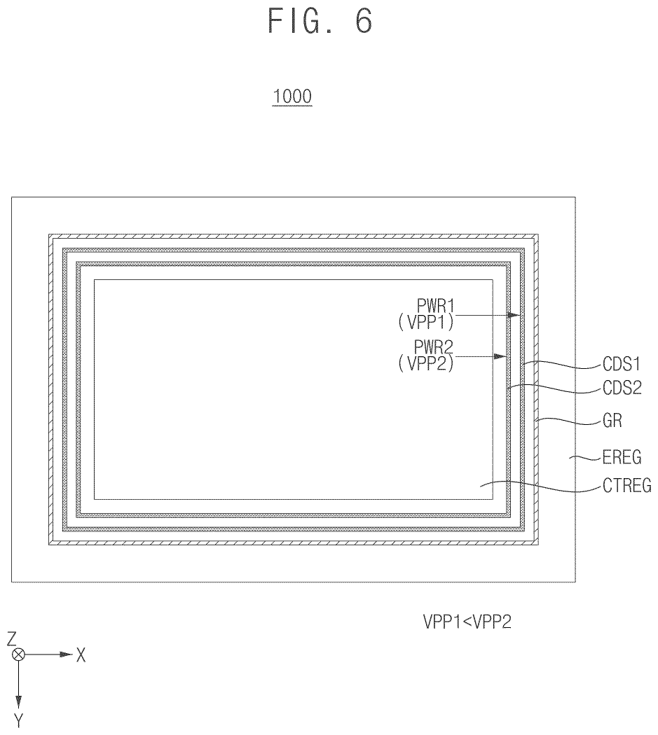

FIG. 6 illustrates an example that a first power and a second power are applied to the first crack detection structure and the second crack detection structure, respectively, in the semiconductor device of FIG. 1.

Referring to FIG. 6, the detection controller 890 in FIG. 1 may apply a first power supply voltage VPP1 as the first power PWR1 and a second power supply voltage VPP2 as the second power PWR2 to the first crack detection structure CDS1 and the second crack detection structure CDS2, respectively, in a first phase. A voltage level of the second power supply voltage VPP2 may be greater than a voltage level of the first power supply voltage VPP1.

When the first power supply voltage VPP1 and the second power supply voltage VPP2 are applied to the first crack detection structure CDS1 and the second crack detection structure CDS2, respectively, an electric field is generated from the second crack detection structure CDS2 to the first crack detection structure CDS1. When the electric field is generated, electrons may move from the first crack detection structure CDS1 to the second crack detection structure CDS2 along a reverse direction of the electric field. When the electrons move from the first crack detection structure CDS1 to the second crack detection structure CDS2, an electrical short circuit may be induced between the first crack detection structure CDS1 and the second crack detection structure CDS2 due to acceleration of a progression of a crack that occurs around the first crack detection structure CDS1 but does not proceed to the first crack detection structure CDS1 and/or to a delamination occurring around the first crack detection structure CDS1, and thus, the first crack detection structure CDS1 is connected to or shorted to at least a portion of the second crack detection structure CDS2. In addition, a progression of a crack occurring in the chip guard ring GR may be accelerated due to the electric field.

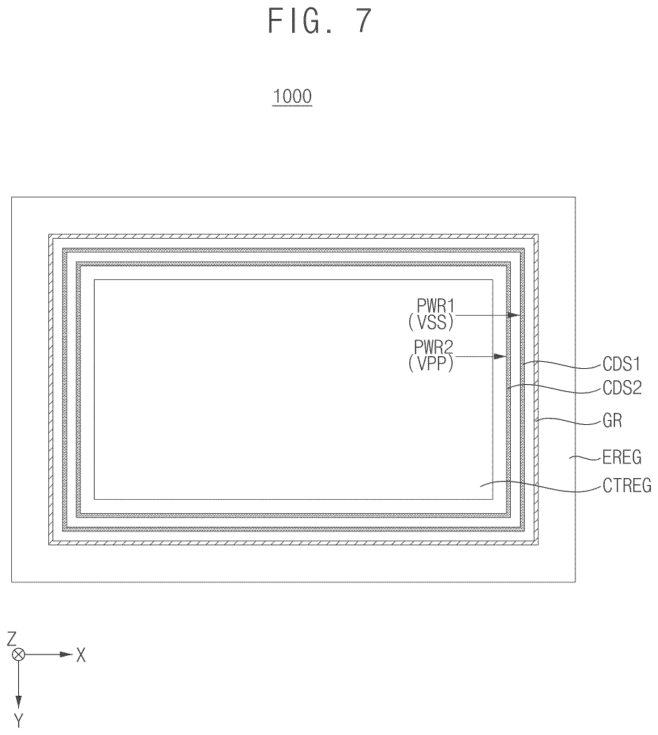

FIG. 7 illustrates an example that a first power and a second power are applied to the first crack detection structure and the second crack detection structure, respectively, in the semiconductor device of FIG. 1.

Referring to FIG. 7, the detection controller 890 in FIG. 1 may apply a ground voltage VSS as the first power PWR1 and a power supply voltage VPP as the second power PWR2 to the first crack detection structure CDS1 and the second crack detection structure CDS2, respectively, in a first phase. A voltage level of the power supply voltage VPP may be greater than a voltage level of the ground voltage VSS.

When the ground voltage VSS and the power supply voltage VPP are applied to the first crack detection structure CDS1 and the second crack detection structure CDS2, respectively, an electric field is generated from the second crack detection structure CDS2 to the first crack detection structure CDS1. When the electric field is generated, electrons may move from the first crack detection structure CDS1 to the second crack detection structure CDS2 along a reverse direction of the electric field. When the electrons move from the first crack detection structure CDS1 to the second crack detection structure CDS2, an electrical short circuit is induced between the first crack detection structure CDS1 and the second crack detection structure CDS2 due to due to acceleration of a progression of a crack that occurs around the first crack detection structure CDS1 but does not proceed to the first crack detection structure CDS1 and/or a delamination occurring around the first crack detection structure CDS1, and thus, the first crack detection structure CDS1 is connected to or shorted to at least a portion of the second crack detection structure CDS2. In addition, a progression of a crack occurring in the chip guard ring GR may be accelerated due to the electric field.

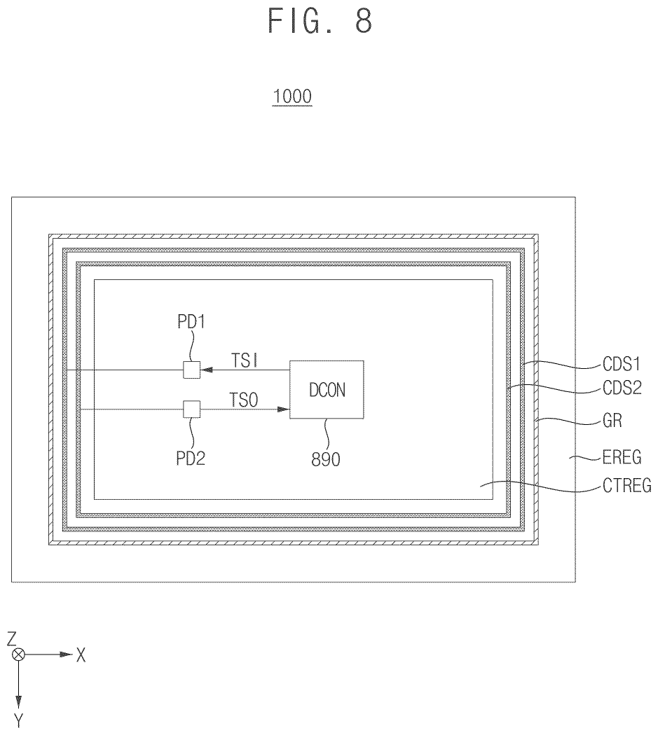

FIG. 8 illustrates signals that are applied to and/or output from the semiconductor device of FIG. 1 in a second phase.

Referring to FIG. 8, after the first phase described with reference to FIGS. 6 and 7 is completed, the detection controller 890 may, in a second phase, apply a test input signal TSI to the first crack detection structure CDS1 through a first pad PD1, may selectively receive a test output signal TSO responding to the test input signal TSI from a second pad PD2, and may determine whether a crack occurs in the central region CTREG based on whether the test output signal TSO is received.

As described with reference to FIGS. 6 and 7, when the first power PWR1 and the second power PWR2 are applied to the first crack detection structure CDS1 and the second crack detection structure CDS2, respectively, in the first phase, a progression of the crack occurring in the chip guard ring GR is accelerated and thus, the detection controller 890 may determine that a crack occurs in the central region CTREG in response to receiving the output signal TSO responding to the test input signal TSI from a second pad PD2 in the second phase.

If a crack does not occur in the chip guard ring GR, a progress of the crack may not be accelerated even when the first power PWR1 and the second power PWR2 are applied to the first crack detection structure CDS1 and the second crack detection structure CDS2, respectively, and the detection controller 890 cannot or is not likely to receive the output signal TSO responding to the test input signal TSI from a second pad PD2 in the second phase. In this case, the detection controller 890 may determine that a crack does not occur in the central region CTREG.

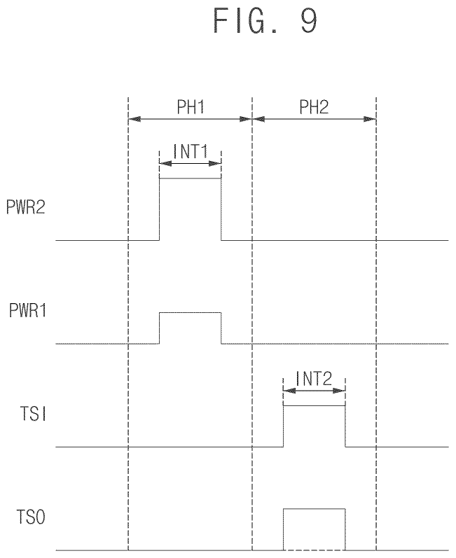

FIG. 9 is a timing diagram illustrating an example operation of the detection controller in FIG. 8 according to some example embodiments.

Referring to FIGS. 8 and 9, the detection controller 890 may apply the first power PWR1 and the second power PWR2 to the first crack detection structure CDS1 and the second crack detection structure CDS2, respectively, during a first time interval INT in a first phase PH1, may apply the test input signal TSI to the first crack detection structure CDS1 during a second time interval INT2 in a second phase PH2 after the first phase PH1, and may selectively receive the test output signal TSO responding to the test input signal TSI from the second crack detection structure CDS2 through the second pad PD2, in the second phase PH2.

When the test output signal TSO responds to the test input signal TSI as denoted by a solid line, the detection controller 890 determines that a crack occurs in the central region CTREG.

When the test output signal TSO does not respond to the test input signal TSI as denoted by a dotted line, the detection controller 890 determines that a crack does not occur in the central region CTREG.

The test input signal TSI may be pulse signal and/or a direct current (DC) voltage.

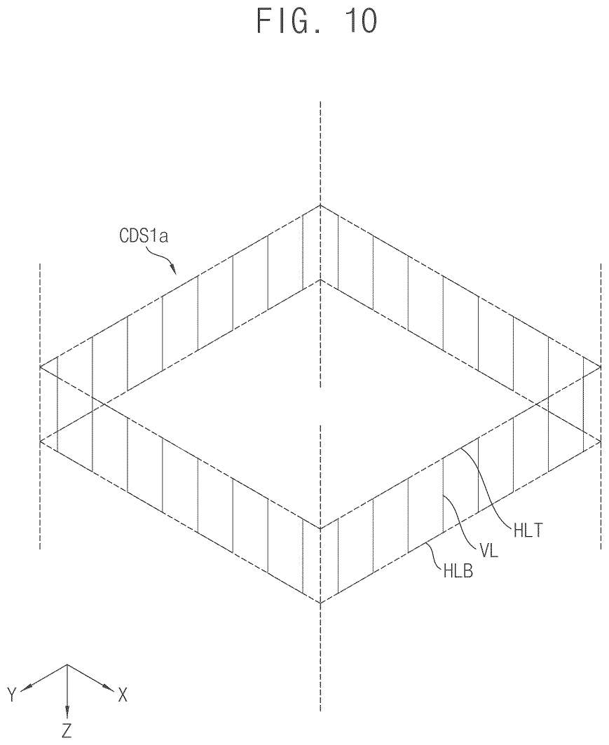

FIG. 10 is a perspective view illustrating an example of a first crack detection structure according to some example embodiments.

Referring to FIG. 10, a first crack detection structure CDS1a may include a single conduction loop. As will be described below, the semiconductor die may include a first conduction layer and a second conduction layer that is provided under the first conduction layer. The conduction layers may include a metal layer in which metal line segments are patterned and/or a polysilicon layer in which polysilicon line segments such as doped polysilicon line segments are patterned. The first crack detection structure CDS1a may expand in the third (vertical) direction Z through the first conduction layer and the second conduction layer.

The first crack detection structure CDS1a may include a plurality of top horizontal line segments HLT formed in the first conduction layer and extending in the first direction X and the second direction Y, a plurality of bottom horizontal line segments HLB formed in the second conduction layer and extending in the first direction X and the second direction Y, a plurality of bottom horizontal line segments HLB formed in the second conduction layer and a plurality of vertical line segments VL connecting the top horizontal line segments HLT and the bottom horizontal line segments HLB respectively in the third direction Z. The top horizontal line segments HLT, the bottom horizontal line segments HLB and the vertical line segments VL may be disposed alternatingly along the first crack detection structure CDS1a to surround the central region CTREG of the semiconductor die.

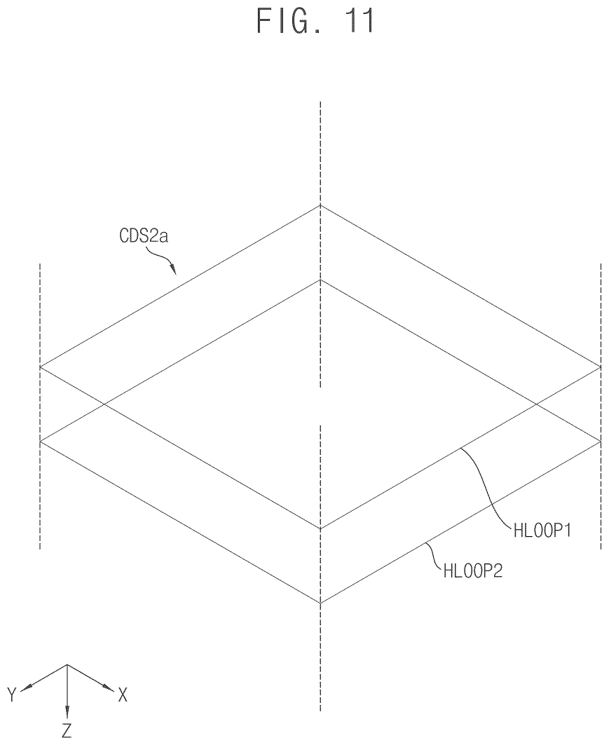

FIG. 11 is a perspective view illustrating an example of a second crack detection structure according to some example embodiments.

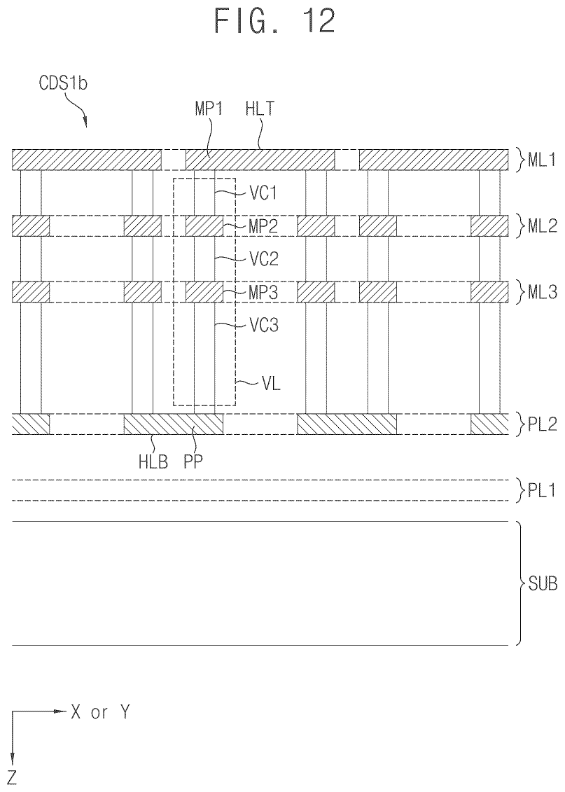

Referring to FIG. 12, a second crack detection structure CDS2a may include a number such as two conduction loops. As will be described below, the semiconductor die may include a first conduction layer and a second conduction layer that is provided under the first conduction layer. The conduction layers may independently or jointly include a metal layer in which metal line segments are patterned and/or a polysilicon layer or doped polysilicon layer in which polysilicon line segments are patterned. The second crack detection structure CDS2a may include conduction loops formed in the first conduction layer and the second conduction layer, respectively.

The second crack detection structure CDS2a may include a first horizontal conduction loop HLOOP1 formed in the first conduction layer and a second horizontal conduction loop HLOOP2 formed in the second conduction layer. The first horizontal conduction loop HLOOP1 may correspond to the plurality of top horizontal line segments HLT in FIG. 10 and the second horizontal conduction loop HLOOP2 may correspond to the plurality of bottom horizontal line segments HLB in FIG. 10.

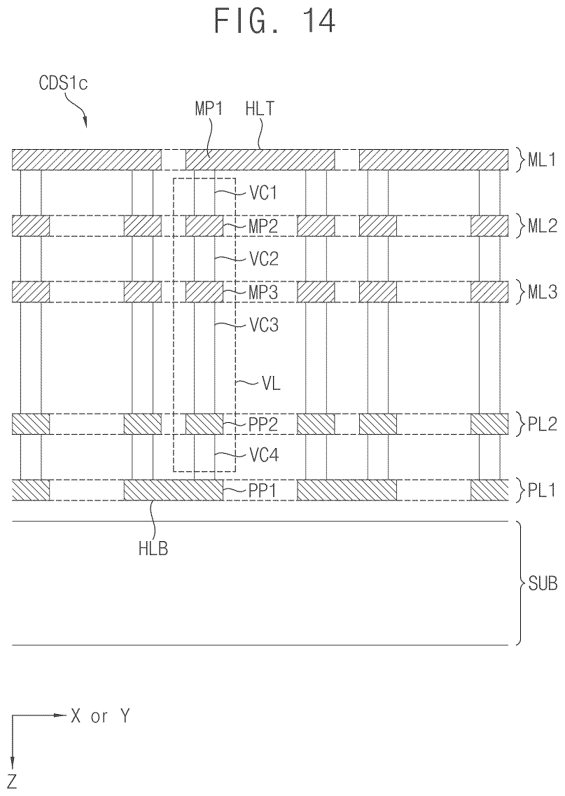

FIGS. 12 and 14 are cross-sectional diagrams illustrating a vertical structure of a first crack detection structure according to some example embodiments.

Referring to FIG. 12, a semiconductor die may include a semiconductor substrate SUB and a dielectric layer in which upper structures are formed. The dielectric layer may include a plurality of conduction layers ML1, ML2, ML3, PL1 and PL2 in which conduction line patterns are formed. Although five layers ML1, ML2, ML3, PL1, and PL2 are illustrated, example embodiments may have more than or fewer than five layers. The conduction layers may include one or more metal layers ML1, ML2 and ML3 and one or more polysilicon layers PL1 and PL2. The polysilicon layers may include a polysilicon layer PL1 in which gates of transistors (not shown) in the semiconductor integrated circuit are formed. In some example embodiments, for example if the semiconductor integrated circuit is a semiconductor memory device, the polysilicon layers may further include a bit-line polysilicon layer PL2 in which bit-lines (not shown) in the semiconductor integrated circuit are formed.

A first crack detection structure CDS1b may include a plurality of top horizontal line segments HLT formed in the first conduction layer ML1, a plurality of bottom horizontal line segments HLB formed in the second conduction layer PL2 and a plurality of vertical line segments VL connecting the top horizontal line segments HLT and the bottom horizontal line segments HLB respectively.

In various example embodiments such as illustrated in FIG. 12, the first conduction layer ML1 may correspond to an uppermost metal layer among the metal layer ML1, ML2 and ML3 that are formed over the semiconductor substrate SUB, and the second conduction layer PL2 may correspond to the bit-line polysilicon layer that is formed between the semiconductor substrate SUB and the metal layers ML1, ML2 and ML3. The top horizontal line segments HLT may include metal line patterns MP1 formed in the uppermost metal layer ML1, and the bottom horizontal line segments HLB may include polysilicon line patterns PP formed in the bit-line polysilicon layer PL2.

The vertical line segments VL may include vertical contacts VC1, VC2 and VC3 to provide an electrical connection between the metal line patterns MP1 in the uppermost metal layer ML1 and the polysilicon line patterns PP in the bit-line polysilicon layer PL2. The vertical line segments VL may further include conduction line patterns MP2 and MP3 in the respective intermediate conduction layers ML2 and ML3. In some example embodiments, the conduction line pattern in one or both of the intermediate conduction layers ML2 and ML3 may be omitted. For example, the metal line patterns MP2 in the intermediate metal layer ML2 may be omitted, and the two vertical contacts VC1 and VC2 may be combined as a longer vertical contact.

Hereinafter, the descriptions repeated with FIG. 12 may be omitted.

Referring to FIG. 14, a first crack detection structure CDS1c may include a plurality of top horizontal line segments HLT formed in the first conduction layer ML1, a plurality of bottom horizontal line segments HLB formed in the second conduction layer PL1, and a plurality of vertical line segments VL connecting the top horizontal line segments HLT and the bottom horizontal line segments HLB respectively.

In various example embodiments for example as illustrated in FIG. 14, the first conduction layer ML1 may correspond to an uppermost metal layer among the metal layers ML1, ML2 and ML3 that are formed over the semiconductor substrate SUB, and the second conduction layer PL1 may correspond to the gate polysilicon layer that is formed between the semiconductor substrate SUB and the metal layers ML1, ML2 and ML3. The top horizontal line segments HLT may include metal line patterns MP1 formed in the uppermost metal layer ML1, and the bottom horizontal line segments HLB may include polysilicon line patterns PP1 formed in the gate polysilicon layer PL1.

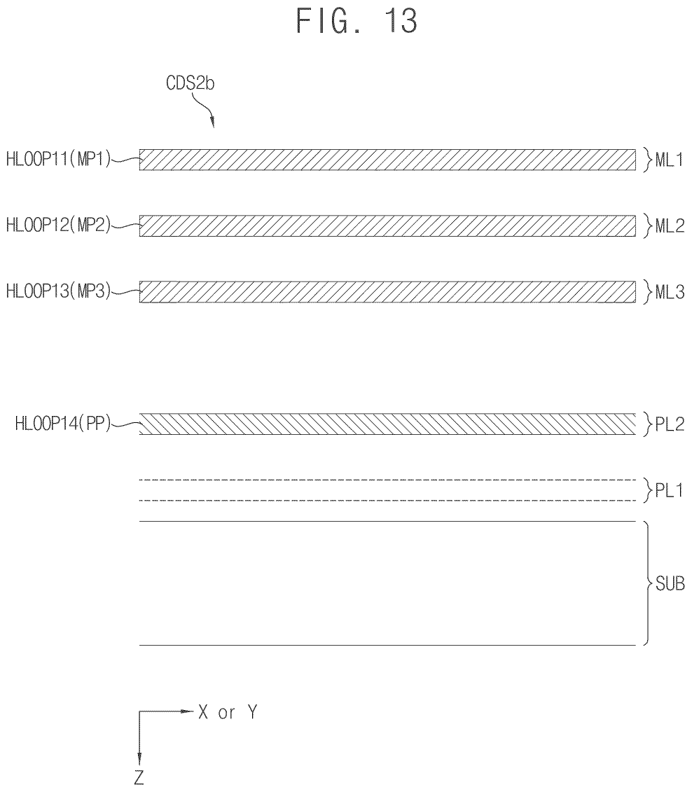

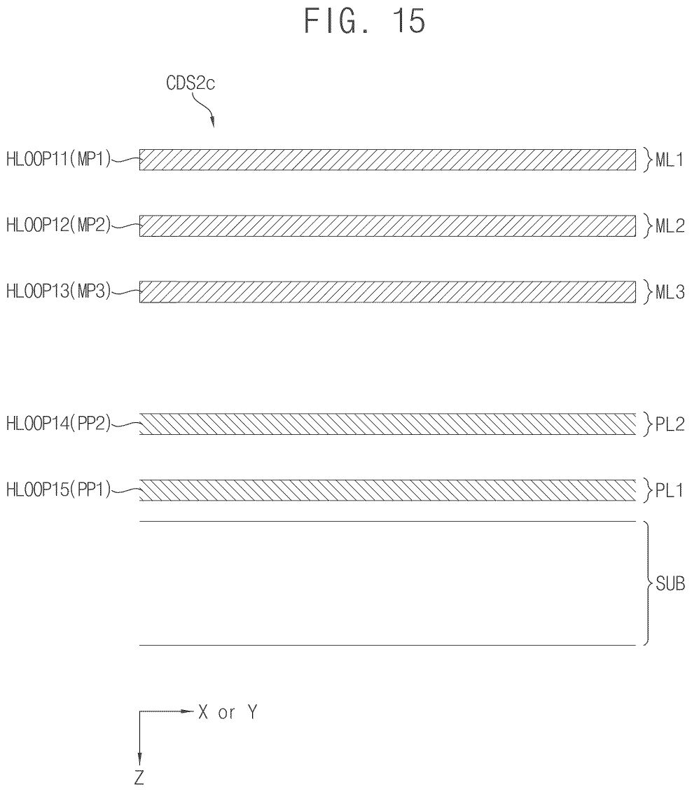

FIGS. 13 and 15 are cross-sectional diagrams illustrating a vertical structure of a second crack detection structure according to some example embodiments.

Referring to FIG. 13, a second crack detection structure CDS2b may include a plurality of horizontal conduction loops HLOOP11, HLOOP12, HLOOP13 and HLOOP14 formed in the plurality of conduction layer ML1, ML2, ML3 and PL1, respectively.

The horizontal conduction loop HLOOP11 may include metal line patterns MP1 formed in the first conduction layer ML1, the horizontal conduction loop HLOOP12 may include metal line patterns MP2 formed in the second conduction layer ML2, the horizontal conduction loop HLOOP13 may include metal line patterns MP4 formed in the third conduction layer ML3 and the horizontal conduction loop HLOOP14 may include polysilicon line patterns PP formed in the bit-line polysilicon layer PL2. The second crack detection structure CDS2b may correspond to the first crack detection structure CDS1b of FIG. 12.

Referring to FIG. 15, a second crack detection structure CDS2c may include a plurality of horizontal conduction loops HLOOP11, HLOOP12, HLOOP13, HLOOP14 and HLOOP15 formed in the plurality of conduction layer ML1, ML2, ML3, PL1, respectively.

The horizontal conduction loop HLOOP11 may include metal line patterns MP1 formed in the first conduction layer ML1, the horizontal conduction loop HLOOP12 may include metal line patterns MP2 formed in the second conduction layer ML2, the horizontal conduction loop HLOOP13 may include metal line patterns MP4 formed in the third conduction layer ML3, the horizontal conduction loop HLOOP14 may include polysilicon line patterns PP2 formed in the bit-line polysilicon layer PL2 and the horizontal conduction loop HLOOP15 may include polysilicon line patterns PP1 formed in the bit-line polysilicon layer PL1. The second crack detection structure CDS2c may correspond to the second crack detection structure CDS1c of FIG. 14.

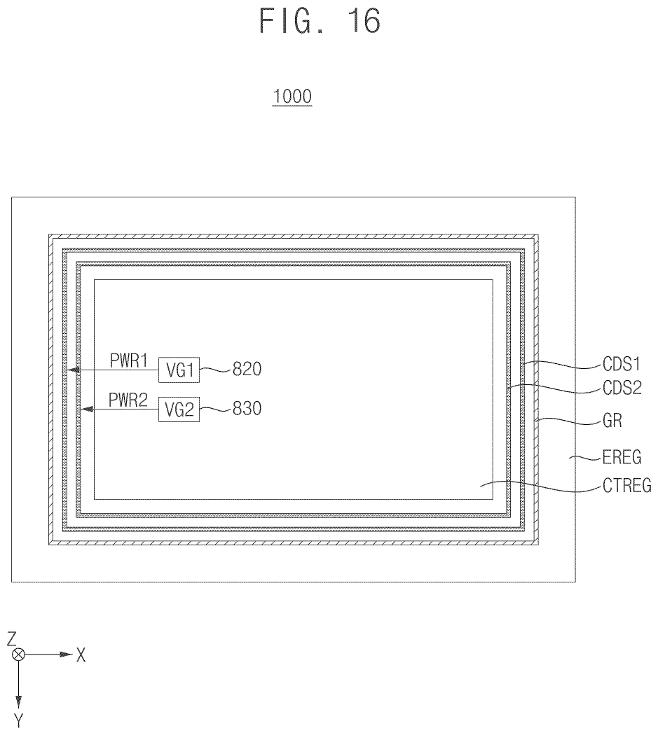

FIGS. 16, 17 and 18 illustrate examples that a first power and a second power are applied to the first crack detection structure and the second crack detection structure, respectively, in the semiconductor device of FIG. 1.

Referring to FIG. 16, the detection controller 890 in FIG. 1 may apply the first power PWR1 to the first crack detection structure CDS1 by using a first voltage generator VG1 820 disposed in the central region CTREG in the first phase and may apply the second power PWR2 to the second crack detection structure CDS2 by using a second voltage generator VG2 830 disposed in the central region CTREG in the first phase.

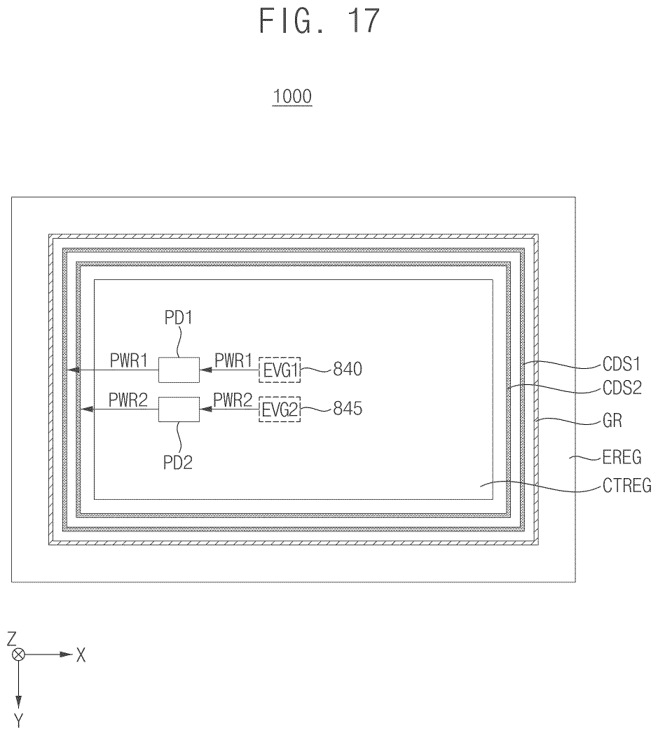

Referring to FIG. 17, the detection controller 890 in FIG. 1 may apply the first power PWR1, which is provided from an external voltage generator EVG1 840 that is external to or outside of the semiconductor device 1000, to the first crack detection structure CDS1 through the first pad PD1 disposed in the central region CTREG in the first phase and may apply the second power PWR2, which is provided from an external voltage generator EVG2 845 external to or outside of the semiconductor device 1000, to the second crack detection structure CDS2 through the second pad PD2 disposed in the central region CTREG in the first phase.

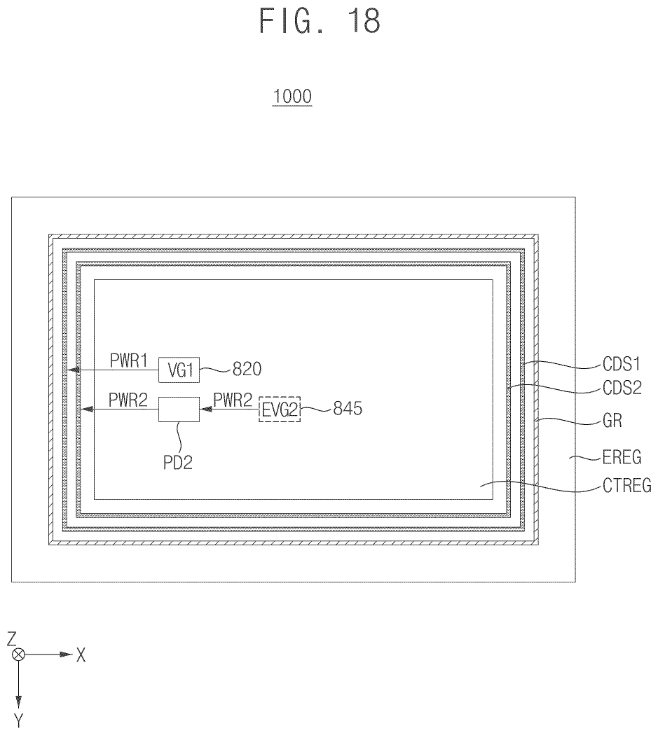

Referring to FIG. 18, the detection controller 890 in FIG. 1 may apply the first power PWR1 to the first crack detection structure CDS1 by using a first voltage generator VG1 820 disposed in the central region CTREG in the first phase and may apply the second power PWR2, which is provided from an external voltage generator EVG2 845 external to the semiconductor device 1000, to the second crack detection structure CDS2 through the second pad PD2 disposed in the central region CTREG in the first phase.

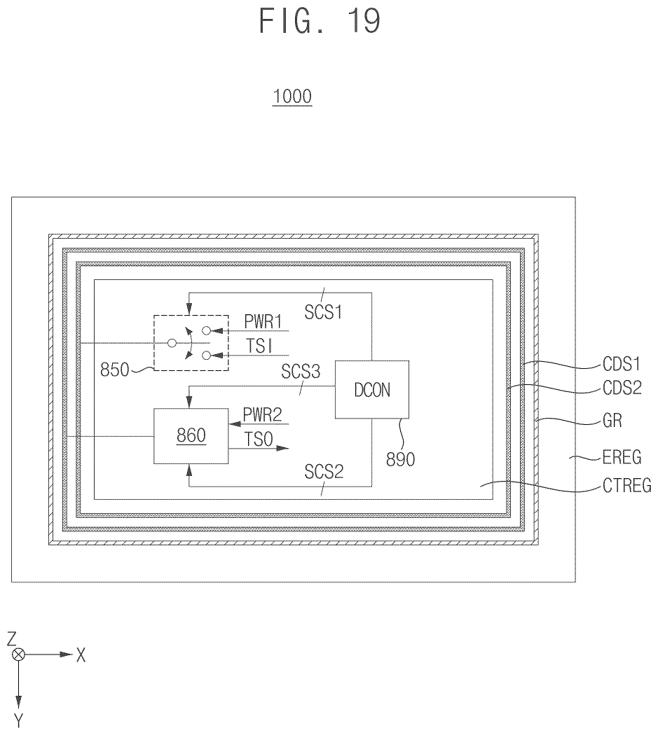

FIG. 19 illustrates the semiconductor device of FIG. 1 according to some example embodiments.

Referring to FIG. 19, the semiconductor device 1000 may further include a first switch circuit 850 and a second switch circuit 860.

The first switch circuit 850 may in response to a first switching control signal SCS1 provide the first power PWR1 to the first crack detection structure CDS1 during the first time interval in the first phase, and may provide the test input signal TSI to the first crack detection structure CDS1 during the second time interval in the second phase.

The second switch circuit 860, may in response to a second switching control signal SCS2 and a third switching control signal SCS3 provide the second power PWR2 to the second crack detection structure CDS2 during the first time interval in the first phase, and may connect the second crack detection structure CDS2 to the detection controller 890 during the second time interval in the second phase and thus, may provide the detection controller 890 with the test output signal TSO responding to the test input signal TSI.

The detection controller 890 may apply the first switching control signal SCS1 to the first switch circuit 850, may apply the second switching control signal SCS2 and the third switching control signal SCS3 to the second switch circuit 860, and may apply the test input signal TSI to the first switch circuit 850 during the second time interval in the second phase.

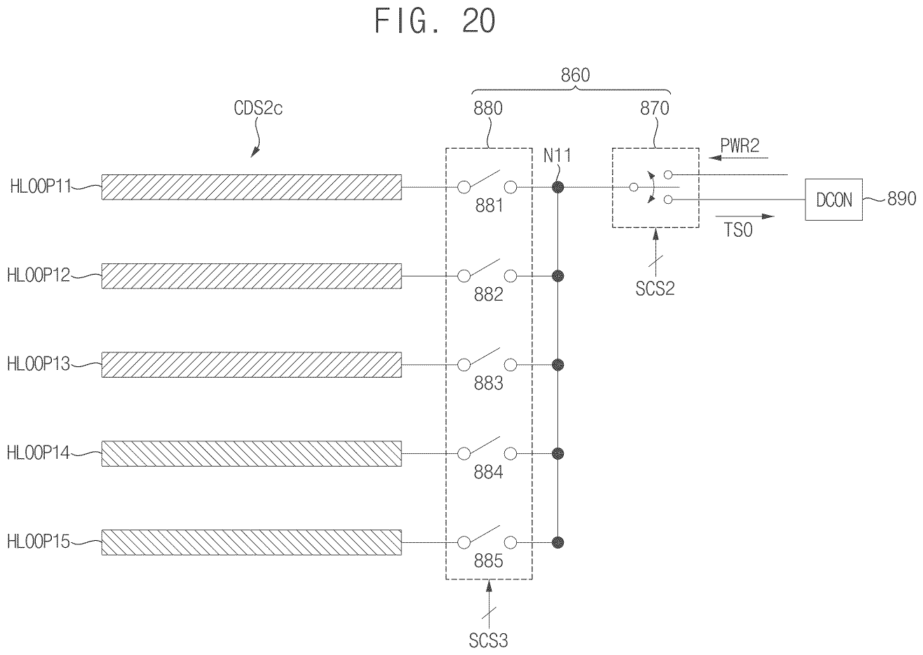

FIG. 20 illustrates an example of the second switch circuit in the semiconductor device of FIG. 19 according to some example embodiments.

In FIG. 20 the second crack detection structure CDS2c and the detection controller 890 are also illustrated for convenience of explanation.

Referring to FIG. 20, the second crack detection structure CDS2c may include the plurality of horizontal conduction loops HLOOP11, HLOOP12, HLOOP13, HLOOP14 and HLOOP15.

The second switch circuit 860 may include a first sub switch 870 and a second sub switch group 880 and the second sub switch group 880 may include a plurality of second sub switches 881, 882, 883, 884 and 885.

The first sub switch 870 may be connected between the detection controller 890 and a first node N11. The plurality of second sub switches 881, 882, 883, 884 and 885 may be commonly connected to the first node N11 and may be connected to the plurality of horizontal conduction loops HLOOP11, HLOOP12, HLOOP13, HLOOP14 and HLOOP15, respectively.

The first sub switch 870, in response to the second switching control signal SCS2, may provide the second power PWR2 to the first node N11 in the first phase and may connect the first node N11 to the detection controller 890 in the second phase.

The plurality of second sub switches 881, 882, 883, 884, and 885 may in response to the third switching control signal SCS3 provide the plurality of horizontal conduction loops HLOOP11, HLOOP12, HLOOP13, HLOOP14 and HLOOP15 with the second power PWR2 provided to the first node N11 in the first phase and may connect at least a portion of the plurality of horizontal conduction loops to HLOOP11, HLOOP12, HLOOP13, HLOOP14 and HLOOP15 to the detection controller 890 through the first node N11 and the first sub switch 870 in the second phase to provide the test output signal TSO to the detection controller 890.

In some example embodiments, the plurality of second sub switches 881, 882, 883, 884, and 885 may in response to the third switching control signal SCS3 provide all of the plurality of horizontal conduction loops HLOOP11, HLOOP12, HLOOP13, HLOOP14 and HLOOP15 with the second power PWR2 provided to the first node N11 in the first phase, and sequentially connect the plurality of horizontal conduction loops to HLOOP11, HLOOP12, HLOOP13, HLOOP14 and HLOOP15 to the detection controller 890 through the first node N11 and the first sub switch 870 in the second phase.

When the plurality of horizontal conduction loops to HLOOP11, HLOOP12, HLOOP13, HLOOP14 and HLOOP15 are sequentially connected to the detection controller 890 through the first node N11 and the first sub switch 870 in the second phase and the test output signal TSO in responding to the test input signal TSI is detected, at least one of the plurality of horizontal conduction loops to HLOOP11, HLOOP12, HLOOP13, HLOOP14 and HLOOP15 in which a crack occur, may be specified.

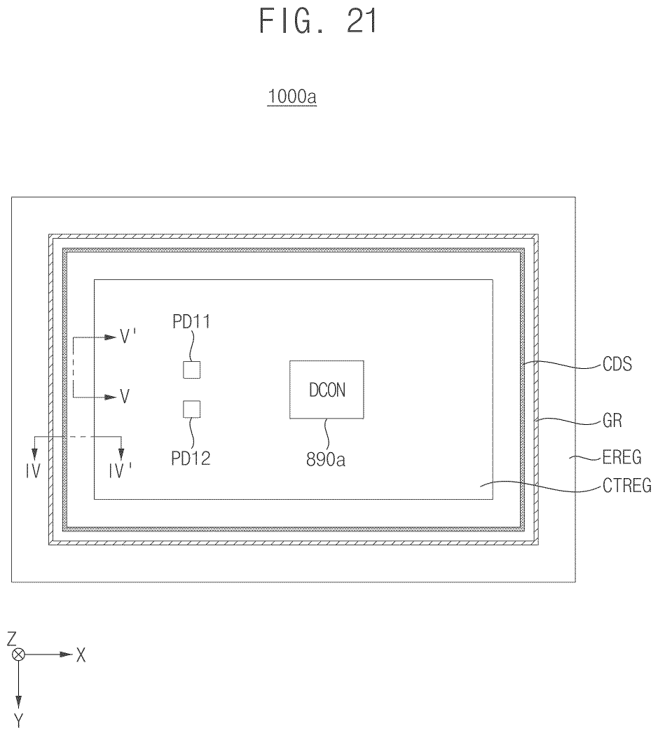

FIG. 21 is a top view illustrating a layout of a semiconductor device according to some example embodiments.

Referring to FIG. 21, a semiconductor device 1000a may include at least one semiconductor die. The semiconductor die may include a central region CTREG and an external region EREG surrounding the central region CTREG. The semiconductor device 1000 may include a chip guard ring GR and a crack detection structure CDS.

Various semiconductor integrated circuits may be formed in the central region CTREG depending on a kind or type of the semiconductor device 1000a. For example, the semiconductor device 1000a may be or include or be included in a nonvolatile memory device and a memory integrated circuit may be formed in the central region CTREG of the semiconductor die.

The external region EREG may be a region in which no element is formed or dummy elements are formed. The external region EREG may be a place having a space margin in case of a damaged part when dicing the wafer to the semiconductor device 1000a.

Even if a crack, e.g., a cracking phenomenon of the semiconductor device 1000a occurs in the external region EREG, there may be no problem in the direct operation of the semiconductor device 1000a. However, when cracks occur in the central region CTREG of the semiconductor device 1000a or proceed from the external region EREG to the central region CTREG, the reliability of the operation of the semiconductor device 1000a may be greatly impaired.

The chip guard ring GR may be formed inside the semiconductor die along an edge of the semiconductor die to separate the central region CTREG and the external region EREG. The chip guard ring GR may be located between the central region CTREG and the external region EREG. The chip guard ring GR may serve to block progress of the above-described cracks from the external region EREG to the central region CTREG.

Alternatively or additionally, the chip guard ring GR may perform a moisture absorption action which prevents or reduces external moisture from entering the inside of the semiconductor device 1000. In other words, when moisture enters the central region CTREG of the semiconductor device 1000, the elements located in the central region CTREG of the semiconductor device 1000a may be damaged or malfunction. The chip guard ring GR may prevent or reduce the likelihood of such problems.

The chip guard ring GR may be formed while making a closed curve along the edge of the semiconductor die. Here, “closed curve” refers to ring shapes that are in contact with one another, but does not necessarily indicate that the extended portion of the chip guard ring GR necessarily has curvature. For example, the horizontal arrangement shape of the chip guard ring GR be a polygon such as a rectangle, rather than a circle or an ellipse.

The crack detection structure CDS may be formed along an edge of the central region CTREG in a form of a closed curve.

The semiconductor device 1000a may further include pads PD11 and PD12 and a detection controller DCON 890a.

The detection controller 890a may induce an electrical short circuit between the crack detection structure CDS and the chip guard ring GR by applying a power to the crack detection structure in a first phase, may apply a test input signal to the chip guard ring GR in a second phase, and may determine whether a progressive crack occurs in the central region CTREG based on whether a test output signal responding to the test input signal is detected in the crack detection structure CDS.

The pads PD11 and PD12 may be selectively used when applying the power to the crack detection structure CDS and applying the test input signal to the chip guard ring GR.

Each of the chip guard ring GR and the crack detection structure may be formed along the first direction X and the second direction Y and may extend in the third direction Z perpendicular to the first direction X and the second direction Y.

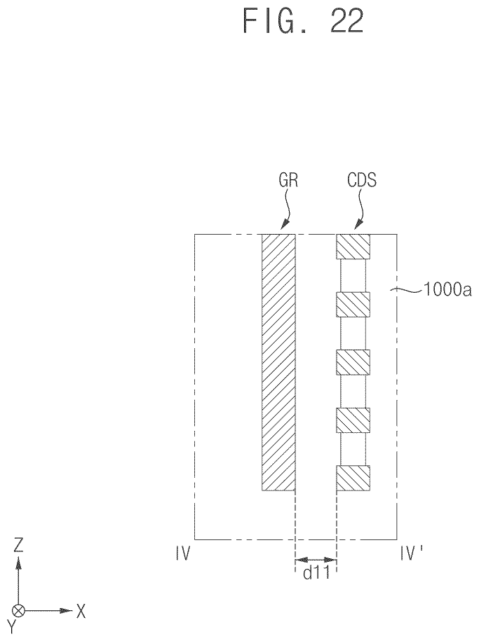

FIG. 22 is a cross-sectional view taken along line IV-IV′ of the semiconductor device of FIG. 21 according to some example embodiments.

Referring to FIG. 22, each of the chip guard ring GR and the crack detection structure CDS may extend in the third direction Z.

The crack detection structure CDS may be spaced apart from the chip guard ring GR by a first gap d11 in the first direction X.

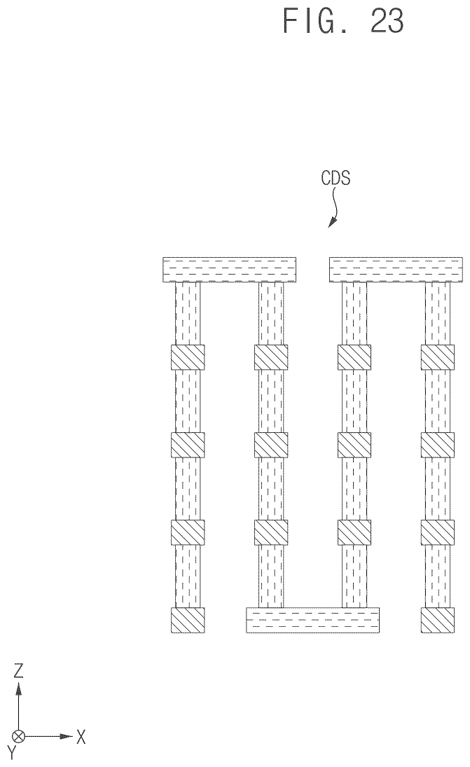

FIG. 23 is a cross-sectional view taken along line V-V′ of the semiconductor device of FIG. 21 according to some example embodiments.

Referring to FIG. 23, the crack detection structure CDS may include a plurality of horizontal lines extending in the first direction X or in the second direction and a plurality of vertical lines that connect each of the plurality of horizontal lines in the third direction Z.

Because the crack detection structure CDS forms a conduction loop, an electric field is generated from the crack detection structure CDS to the chip guard ring GR when a power is applied to the crack detection structure CDS. When the electric field is generated, electrons may move from the chip guard ring GR to the crack detection structure CDS along a reverse direction of the electric field, an electrical short circuit is induced between the chip guard ring GR and the crack detection structure due to a crack and/or a delamination occurring around the crack detection structure CDS, and the crack detection structure CDS and the chip guard ring GR are electrically connected or shorted. Therefore, electrical loading becomes greater and a progressive crack may be detected based on delay of a test output signal.

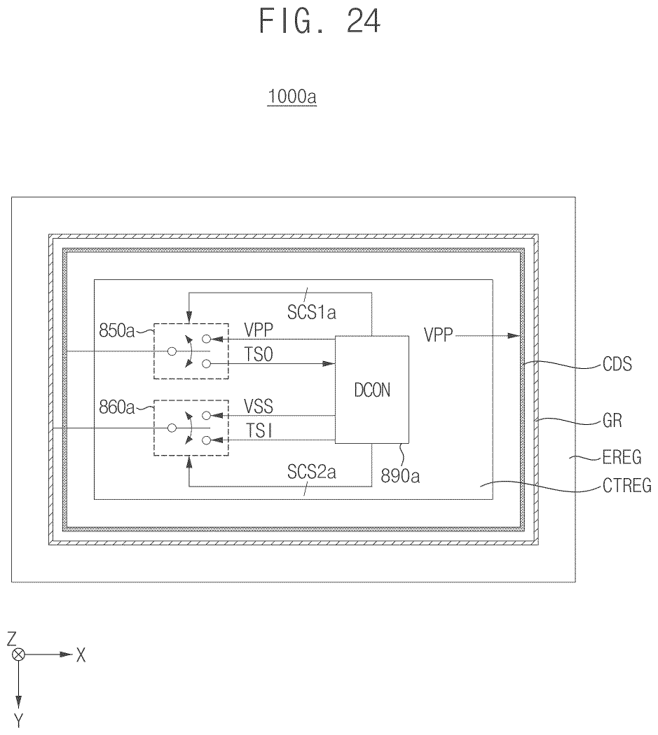

FIG. 24 illustrates the semiconductor device of FIG. 21 according to some example embodiments.

Referring to FIG. 24, the semiconductor device 1000 may further include a first switch circuit 850a and a second switch circuit 860a. The power supply voltage VPP is applied to the crack detection structure CDS.

The first switch circuit 850a may, in response to a first switching control signal SCS1a, provide a power supply voltage VPP to the crack detection structure CDS during a first time interval in a first phase, and may connect the crack detection structure CDS to the detection controller 890a to provide the test output signal TSO to the detection controller 890a during a second time interval in a second phase.

The second switch circuit 860a may, in response to a second switching control signal SCS2a, provide the ground voltage VSS to the chip guard ring GR during the first time interval in the first phase and may provide the test input signal TSI to the chip guard ring GR during the second time interval in the second phase.

When the power supply voltage VPP is applied to the crack detection structure CDS in the first phase, an electric field is generated from the crack detection structure CDS to the chip guard ring GR. When the electric field is generated, electrons move from the chip guard ring GR to the crack detection structure CDS along a reverse direction of the electric field, a progression of a crack occurring in the chip guard ring GR is accelerated due to the electrons and the crack proceeds to the crack detection structure CDS. The detection controller 890a may apply the test input signal TSI to the chip guard ring GR in the second phase and may determine whether a crack occurs in the central region CTREG based on whether the test output signal TSO responding to the test input signal TSI is received.

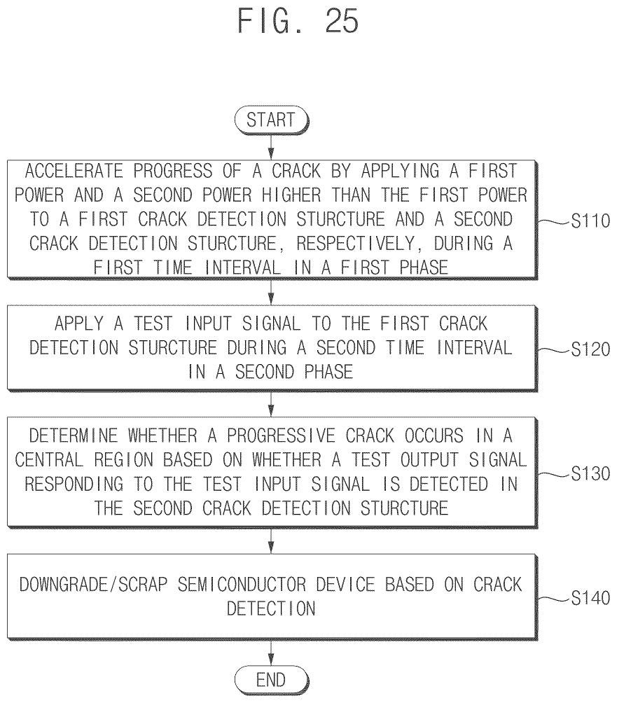

FIG. 25 is a flow chart illustrating a method of detecting a progressive crack in a semiconductor device and of removing or downgrading the semiconductor device according to some example embodiments.

The semiconductor device 1000 may include a semiconductor die and the semiconductor die includes a central region CTREG in which a semiconductor integrated circuit is formed and an external region EREG surrounding the central region CTREG and a chip GR formed along an edge of the semiconductor die to separate the central region CTREG and the external region EREG.

Referring to FIGS. 1 through 20 and 25, for detecting a progressive crack (defect) in the semiconductor device 1000, the detection controller 890 applies a first power PWR1 and a second power PWR2 greater than the first power PWR1 to a first crack detection structure CDS1 and a second crack detection structure CDS2, respectively, during a first time interval in a first phase (operation S110). The first crack detection structure CDS1 is formed along an edge of the central region CTREG in a form of a closed curve, the second crack detection structure CDS2 is formed along the edge of the central region CTREG in a form of a closed curve and the second crack detection structure CDS2 is spaced apart from the chip guard ring farther than the first crack detection structure CDS1.

The detection controller 890 may apply a test input signal TSI to the first crack detection structure CDS1 during a second time interval in a second phase (operation S120).

The detection controller 890 may determine whether a progressive crack occurs in the central region CTREG based on whether a test output signal TSO responding to the test input signal TSI is detected in the second crack detection structure CDS2 in the second phase (operation S130). Based on a result of the test output signal TSO, the semiconductor device may be scrapped or downgraded, leading to an improved yield and/or reliability and/or an earlier detection of inoperable parts and/or a decrease in fabrication time and/or costs (operation S140).

For applying the test input signal TSI to the first crack detection structure CDS1, the detection controller 890 may apply a pulse signal or a DC voltage to the first crack detection structure CDS1 during the second time interval in the second phase. When a pulse signal or a DC voltage is detected in the second crack detection structure CDS2, the detection controller 890 determines that the progressive crack occurs in the central region CTREG.

Accordingly, the semiconductor device according to some example embodiments, may accelerate a progression of a crack occurring around the first crack detection structure by applying a first power and a second power having a voltage level difference to the first crack detection structure and the second crack detection structure, respectively, in the first phase, may apply a pulse signal or a DC voltage to the first crack detection structure in a second phase and may determine whether a progressive crack occurs in the central region based on whether the pulse signal or the DC voltage is detected in the second crack detection structure, in the second phase. Therefore, the semiconductor device according to some example embodiments may be screened when having potential defects and thus reliability of the semiconductor device may be enhanced.

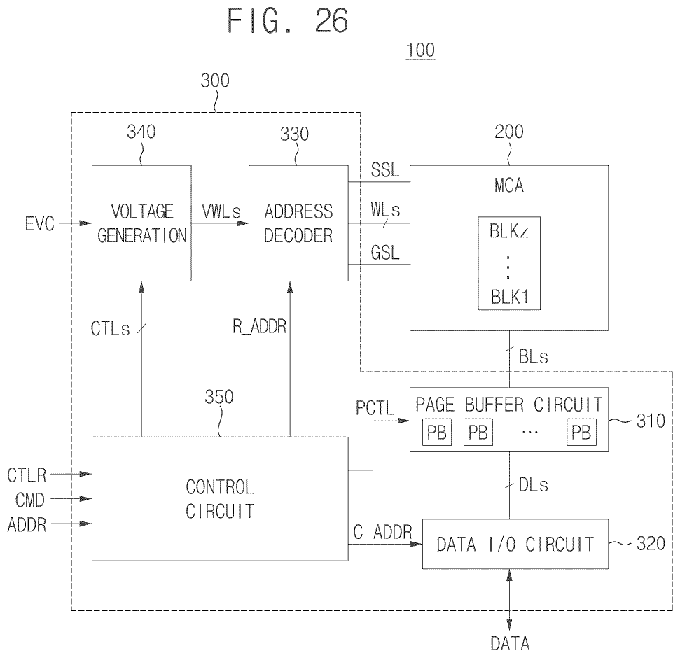

FIG. 26 is a block diagram illustrating a semiconductor device according to some example embodiments.

Hereinafter, it is assumed that a semiconductor device corresponds to a nonvolatile memory device; however, example embodiments are not limited thereto.

Referring to FIG. 26, a nonvolatile memory device 100 may include a memory cell array 200 and a peripheral circuit 300. The peripheral circuit 300 may include a page buffer circuit 310, a data input/output (I/O) circuit 320, a control circuit 350, a voltage generator 340, and an address decoder 330.

The memory cell array 200 may be coupled to the address decoder 330 through a string selection line SSL, a plurality of word-lines WLs, and a ground selection line GSL.

In addition, the memory cell array 200 may be coupled to the page buffer circuit 310 through a plurality of bit-lines BLs. The memory cell array 200 may include a plurality of nonvolatile memory cells coupled to the plurality of word-lines WLs and the plurality of bit-lines BLs.

The memory cell array 200 may include a plurality of memory blocks BLK1 through BLKz, and each of the memory blocks BLK1 through BLKz may have a three-dimensional (3D) structure. Here, z is an integer greater than two. The memory cell array 200 may include a plurality of (vertical) cell strings (e.g., NAND strings) and each of the cell strings includes a plurality of memory cells stacked with respect to each other.

The control circuit 350 may receive a command CMD, an address ADDR, and a control signal CTRL from an external memory controller and may control, for example, an erase loop, a program loop and a read operation of the nonvolatile memory device 100. The program loop may include a program operation and a program verification operation and the erase loop may include an erase operation and an erase verification operation.

In various example embodiments, the control circuit 350 may generate control signals CTLs, which are used for controlling the voltage generator 340, based on the command CMD, may generate a page buffer control signal PCTL for controlling the page buffer circuit 310, and may generate a row address R_ADDR and a column address C_ADDR based on the address ADDR. The control circuit 350 may provide the row address R_ADDR to the address decoder 330, may provide the column address C_ADDR to the data I/O circuit 320, may provide the control signals CTLs to the voltage generator 340 and may provide the page buffer control signal PCTL to the page buffer circuit 310.

The address decoder 330 may be coupled to the memory cell array 200 through the string selection line SSL, the plurality of word-lines WLs, and the ground selection line GSL, During program operation or read operation, the address decoder 330 may determine one of the plurality of word-lines WLs as a selected word-line based on the row address R_ADDR and may determine the rest of the plurality of word-lines WLs except the selected word-line as unselected word-lines.

The voltage generator 340 may generate word-line voltages VWLs associated with operations of the nonvolatile memory device 100 using an external voltage EVC provided from the memory controller based on control signals CTLs from the control circuit 350. The word-line voltages VWLs may be applied to the plurality of word-lines WLs through the address decoder 330.

For example, during the erase operation, the voltage generator 350 may apply an erase voltage to a well of a selected memory block and may apply a ground voltage to all word-lines of the selected memory block. During the erase verification operation, voltage generator 350 may apply an erase verification voltage to all word-lines of the selected memory block or may apply the erase verification voltage to the word-lines of the selected memory block on a word-line basis.

For example, during the program operation, the voltage generator 350 may apply a program voltage to the selected word-line and may apply a program pass voltage to the unselected word-lines. Alternatively or additionally, during the program verification operation, the voltage generator 350 may apply a program verification voltage to the selected word-line and may apply a verification pass voltage to the unselected word-lines. Alternatively or additionally, during the read operation, the voltage generator 350 may apply a read voltage to the selected word-line and may apply a read pass voltage to the unselected word-lines.

The page buffer circuit 310 may be coupled to the memory cell array 200 through the plurality of bit-lines BLs. The page buffer circuit 310 may include a plurality of page buffers PB. The page buffer circuit 310 may temporarily store data to be programmed in a selected page or data read out from the selected page of the memory cell array 200.

In some example embodiments, page buffer units included in each of the plurality of page buffers PB (and cache latches included in each of the plurality of page buffers PB may be spaced apart from each other, and may have separate structures. Accordingly, the degree of freedom of wirings on the page buffer units may be increased, and the complexity of a layout may be reduced. In addition, because the cache latches are adjacent to data I/O lines, the distance between the cache latches and the data I/O lines may be reduced, and thus, data I/O speed may be increased.

The data I/O circuit 320 may be coupled to the page buffer circuit 310 through a plurality of data lines DLs. During the program operation, the data I/O circuit 320 may receive program data DATA from the memory controller and provide the program data DATA to the page buffer circuit 310 based on the column address C_ADDR received from the control circuit 450. During the read operation, the data I/O circuit 320 may provide read data DATA to the memory controller based on the column address C_ADDR received from the control circuit 350.

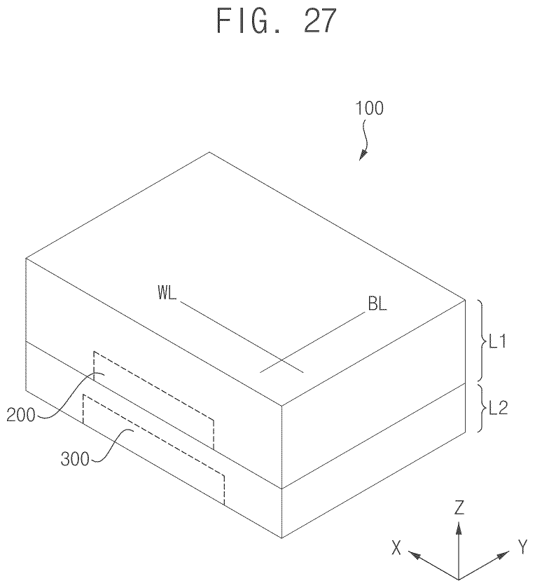

FIG. 27 schematically illustrates a structure of the nonvolatile memory device of FIG. 26 according to some example embodiments.

Referring to FIG. 27, the nonvolatile memory device 100 may include a first semiconductor layer L1 and a second semiconductor layer L2. The first semiconductor layer L1 may be stacked in a vertical direction Z with respect to the second semiconductor layer L2. The second semiconductor layer L2 may be disposed under the first semiconductor layer L1 in the third direction Z, and accordingly, the second semiconductor layer L2 may be close to a substrate. For example, among the first semiconductor layer L1 and the second semiconductor layer L2, the second semiconductor layer L2 may be disposed closer to a substrate.

In some example embodiments, the memory cell array 200 in FIG. 26 may be formed (or provided) on the first semiconductor layer L1, and the peripheral circuit 310 in FIG. 26 may be formed (or provided) on the second semiconductor layer L2.

Accordingly, the nonvolatile memory device 100 may have a structure in which the memory cell array 200 is disposed on the peripheral circuit 300, that is, a cell over periphery (COP) structure. The COP structure may effectively reduce an area in a horizontal direction and increase the degree of integration of the nonvolatile memory device 100.

In some example embodiments, the second semiconductor layer L2 may include a substrate, and by forming transistors on the substrate and metal patterns for wiring transistors, the peripheral circuit 300 may be formed in the second semiconductor layer L2. After the peripheral circuit 300 is formed on the second semiconductor layer L2, the first semiconductor layer L1 including the memory cell array 200 may be formed, and the metal patterns for connecting the word-lines WL and the bit-lines BL of the memory cell array 200 to the peripheral circuit 300 formed in the second semiconductor layer L2 may be formed. For example, the word-lines WL may extend in the first direction X and the bit-lines BL may extend in the second direction Y.

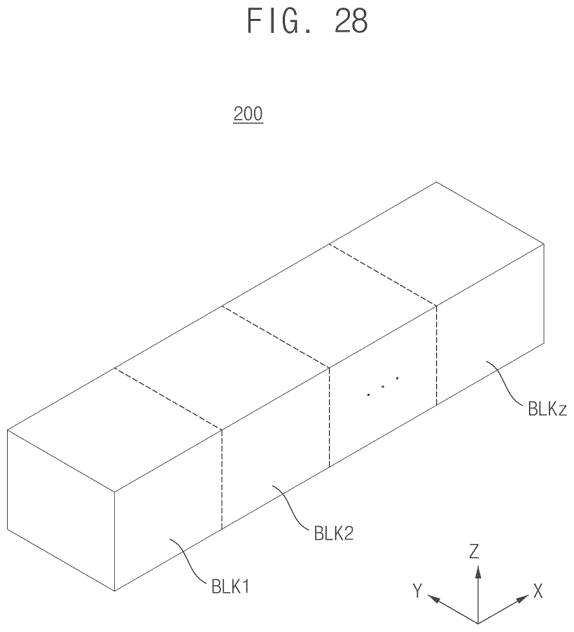

FIG. 28 is a block diagram illustrating an example of the memory cell array in FIG. 26 according to some example embodiments.

Referring to FIG. 28 the memory cell array 200 may include a plurality of memory blocks BLK1 to BLKz which extend along a plurality of directions including the first direction X, the second direction Y and the third direction Z. In an embodiment, the memory blocks BLK1 to BLKz are selected by the address decoder 330 in FIG. 27. For example, the address decoder 330 may select a memory block BLK corresponding to a block address among the memory blocks BLK1 to BLKz.

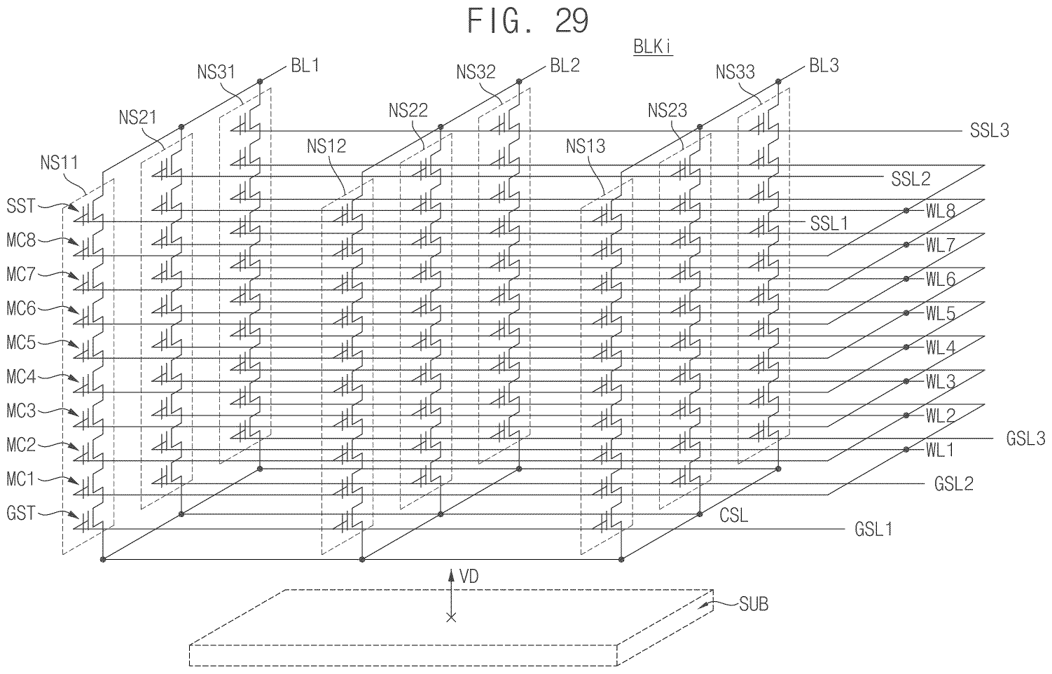

FIG. 29 is a circuit diagram illustrating one of the memory blocks of FIG. 28 according to some example embodiments.

The memory block BLKi of FIG. 29 may be formed on a substrate SUB in a three-dimensional structure (or a vertical structure). For example, a plurality of memory cell strings included in the memory block BLKi may be formed in the vertical direction VD substantially perpendicular to the substrate SUB. Here, i corresponds to one of 1 to z.

Referring to FIG. 29, the memory block BLKi may include cell strings (or, NAND strings) NS11 to NS33 coupled between bit-lines BL1, BL2 and BL3 and a common source line CSL. Each of the cell strings NS11 to NS33 may include a string selection transistor SST, a plurality of memory cells MC1 to MC8, and a ground selection transistor GST. In FIG. 29, each of the cell strings NS11 to NS33 is illustrated to include eight memory cells MC1 to MC8. However, example embodiments are not limited thereto. For example, in some example embodiments, each of the cell strings NS11 to NS33 may include any number of memory cells.

The string selection transistor SST may be connected to corresponding string selection lines SSL1 to SSL3. The plurality of memory cells MC1 to MC8 may be connected to corresponding word-lines WL1 to WL8, respectively. The ground selection transistor GST may be connected to corresponding ground selection lines GSL1 to GSL3. The string selection transistor SST may be connected to corresponding bit-lines BL1, BL2 and BL3, and the ground selection transistor GST may be connected to the common source line CSL.

Word-lines (e.g., WL1) having the same height may be commonly connected, and the ground selection lines GSL1 to GSL3 and the string selection lines SSL1 to SSL3 may be separated.

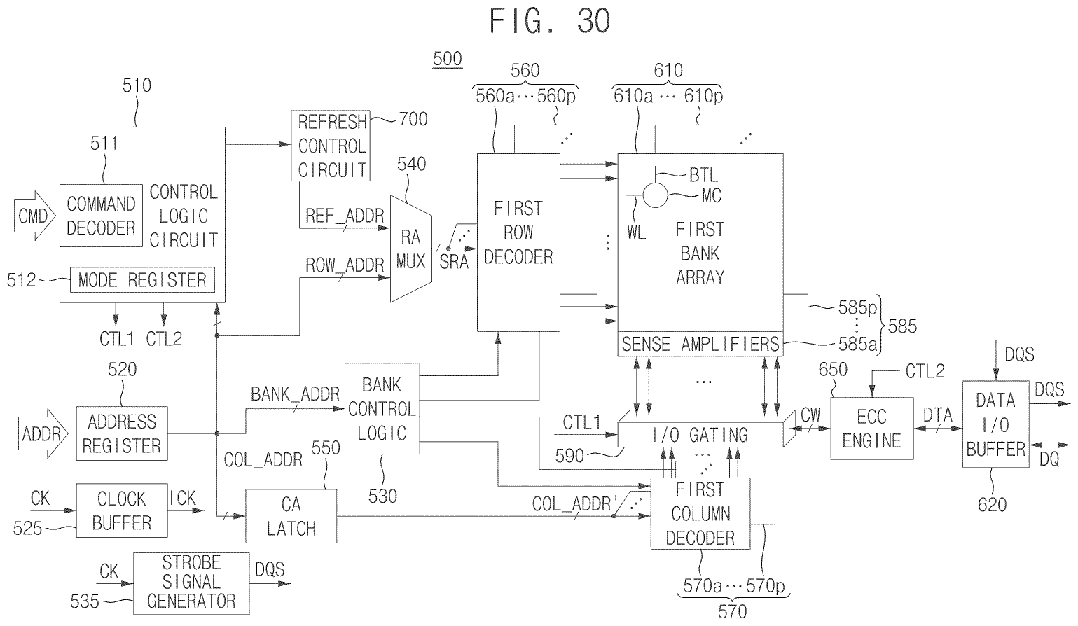

FIG. 30 is a block diagram illustrating an example of the semiconductor device in FIG. 1 according to some example embodiments.

Referring to FIG. 30, the semiconductor device 500 may be a volatile memory device and may include the control logic circuit 510, an address register 520, a bank control logic 530, a refresh control circuit 700, a row address multiplexer 540, a column address latch 550, a row decoder 560, a column decoder 570, a memory cell array 610, a sense amplifier unit 585, an I/O gating circuit 590, an error correction code (ECC) engine 650, a clock buffer 625, a strobe signal generator 235 and a data I/O buffer 620.

The memory cell array 610 may include first through sixteenth bank arrays 610a˜610p. The row decoder 560 may include first through sixteenth row decoders 560a˜560p respectively coupled to the first through sixteenth bank arrays 610a˜610p, the column decoder 570 may include first through sixteenth column decoders 570a˜570p respectively coupled to the first through sixteenth bank arrays 610a˜610p, and the sense amplifier unit 585 may include first through sixteenth sense amplifiers 585a˜585p respectively coupled to the first through sixteenth bank arrays 610a˜610p.

The first through sixteenth bank arrays 610a˜610p, the first through sixteenth row decoders 560a˜560p, the first through sixteenth column decoders 570a˜570p and first through sixteenth sense amplifiers 585a˜585p may form first through sixteenth banks. Each of the first through sixteenth bank arrays 610a˜610p includes a plurality of memory cells MC formed at intersections of a plurality of word-lines WL and a plurality of bit-lines BTL.

The address register 520 may receive the address ADDR including a bank address BANK_ADDR, a row address ROW_ADDR and a column address COL_ADDR from an external memory controller. The address register 520 may provide the received bank address BANK_ADDR to the bank control logic 530, may provide the received row address ROW_ADDR to the row address multiplexer 540, and may provide the received column address COL_ADDR to the column address latch 550.

The bank control logic 530 may generate bank control signals in response to the bank address BANK_ADDR. One of the first through sixteenth row decoders 560a˜560s corresponding to the bank address BANK_ADDR is activated in response to the bank control signals, and one of the first through sixteenth column decoders 570a˜570p corresponding to the bank address BANK_ADDR is activated in response to the bank control signals.

The row address multiplexer 540 may receive the row address ROW_ADDR from the address register 520, and may receive a refresh row address REF_ADDR from the refresh control circuit 700. The row address multiplexer 540 may selectively output the row address ROW_ADDR or the refresh row address REF_ADDR as a row address SRA. The row address SRA that is output from the row address multiplexer 240 is applied to the first through sixteenth row decoders 560a˜560p.

The refresh control circuit 700 may sequentially increase or decrease the refresh row address REF_ADDR in a normal refresh mode under control the control logic circuit 510.

The activated one of the first through sixteenth row decoders 560a˜560p, by the bank control logic 530, may decode the row address SRA that is output from the row address multiplexer 540, and may activate a word-line corresponding to the row address SRA. For example, the activated bank row decoder applies a word-line driving voltage to the word-line corresponding to the row address.

The column address latch 550 may receive the column address COL_ADDR from the address register 520, and may temporarily store the received column address COL_ADDR. In some embodiments, in a burst mode, the column address latch 550 may generate column address COL_ADDR′ that increment from the received column address COL_ADDR. The column address latch 550 may apply the temporarily stored or generated column address COL_ADDR′ to the first through sixteenth column decoders 570a˜570p.

The activated one of the first through sixteenth column decoders 570a˜570p activates a sense amplifier corresponding to the bank address BANK_ADDR and the column address COL_ADDR through the I/O gating circuit 590.

The I/O gating circuit 590 may include a circuitry for gating input/output data, and may further include input data mask logic, read data latches for storing data that is output from the first through sixteenth bank arrays 610a˜610p, and write drivers for writing data to the first through sixteenth bank arrays 610a˜610p.

Codeword CW read from a selected one bank array of the first through sixteenth bank arrays 610a˜610s is sensed by a sense amplifier coupled to the selected one bank array from which the data is to be read, and is stored in the read data latches. The codeword CW stored in the read data latches may be provided to the data I/O buffer 620 as data DTA after ECC decoding is performed on the codeword CW by the ECC engine 650. The data I/O buffer 620 may convert the data DTA into the data signal DQ and may transmit the data signal DQ along with the data strobe signal DQS to the memory controller.

The data signal DQ to be written in a selected one bank array of the first through sixteenth bank arrays 610a˜610p may be provided to the data I/O buffer 320 from the memory controller. The data I/O buffer 620 may convert the data signal DQ to the data DTA and may provide the data DTA to the ECC engine 650. The ECC engine 650 may perform an ECC encoding on the data DTA to generate parity bits, and the ECC engine 650 may provide the codeword CW including data DTA and the parity bits to the I/O gating circuit 590. The I/O gating circuit 590 may write the codeword CW in a sub-page in the selected one bank array through the write drivers.

The data I/O buffer 620 may provide the data signal DQ from the memory controller to the ECC engine 650 by converting the data signal DQ to the data DTA in a write operation of the semiconductor device 500 and may convert the data DTA to the data signal DQ from the ECC engine 650 and may transmit the data signal DQ and the data strobe signal DQS to the memory controller in a read operation of the semiconductor device 500.

The ECC engine 650 may perform an ECC encoding on the data DTA and may perform an ECC decoding on the codeword CW based on a second control signal CTL2 from the control logic circuit 510.

The clock buffer 525 may receive the clock signal CK, may generate an internal clock signal ICK by buffering the clock signal CK, and may provide the internal clock signal ICK to circuit components processing the command CMD and the address ADDR.

The strobe signal generator 535 may receive the clock signal CK, may generate the data strobe signal DQS based on the clock signal CK and may provide the data strobe signal DQS to the data I/O buffer 620.

The control logic circuit 510 may control operations of the semiconductor device 500. For example, the control logic circuit 510 may generate control signals for the semiconductor device 500 in order to perform a write operation, a read operation, a normal refresh operation. The control logic circuit 510 may include a command decoder 511 that decodes the command CMD received from the memory controller and a mode register 512 that sets an operation mode of the semiconductor device 500.

For example, the command decoder 511 may generate the control signals corresponding to the command CMD by decoding a write enable signal, a row address strobe signal, a column address strobe signal, a chip select signal, etc. The control logic circuit 510 may provide a first control signal CTL1 to the I/O gating circuit 590, and a second control signal CTL2 to the ECC engine 650.

The semiconductor device 500 of FIG. 30 may be provided in the central region CTREG in FIG. 1.

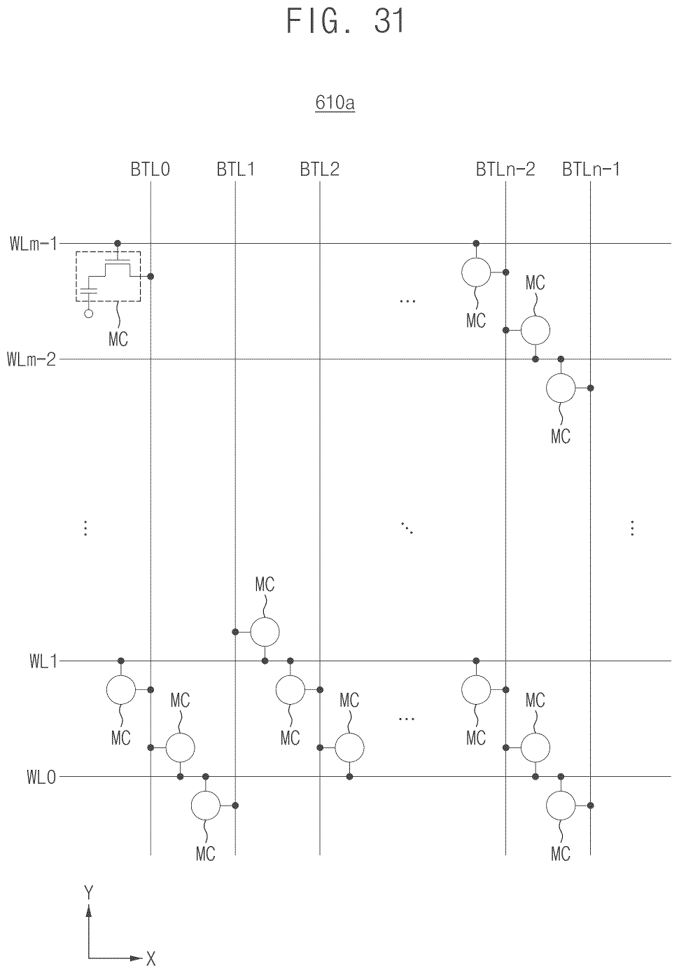

FIG. 31 illustrates an example of the first bank array in the semiconductor device of FIG. 30.

Referring to FIG. 31, the first bank array 310a includes a plurality of word-lines WL0˜WLm-1 (m is a natural number greater than two), a plurality of bit-lines BTL0˜BTLn-1 (n is a natural number greater than two), and a plurality of memory cells MCs disposed at intersections between the word-lines WL0˜WLm-1 and the bit-lines BTL0˜BTLn-1. Each of the memory cells MCs includes a cell transistor coupled to each of the word-lines WL0˜WLm-1 and each of the bit-lines BTL0˜BTLn-1 and a cell capacitor coupled to the cell transistor. Each of the memory cells MCs may have a DRAM cell structure. Each of the word-lines WL0˜WLm-1 extends in the first direction X and each of the bit-lines BTL1˜BTLn-1 extends in a second direction Y crossing the first direction D1.

The word-lines WL0˜WLm-1 coupled to the plurality of memory cells MCs may be referred to as rows of the first bank array 610a and the bit-lines BTL0˜BTLn-1 coupled to the plurality of memory cells MCs may be referred to as columns of the first bank array 610a.

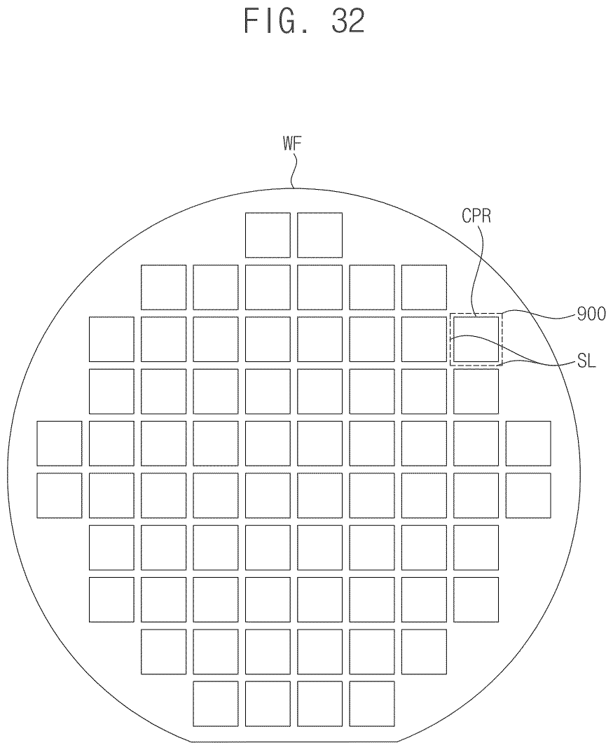

FIG. 32 is a plan view for explaining a semiconductor device according to some example embodiments.

In FIG. 32, a wafer WF is illustrated for describing manufacturing processes of a semiconductor device according to some example embodiments. A diameter of the wafer WF may be 200 mm, or 300 mm or 450 mm; example embodiments are not limited thereto. A plurality of chip regions CPR and scribe lanes SL surrounding the chip regions CPR are formed in the wafer WF. The wafer WF is cut along the scribe lanes SL and divided into a plurality of dies. Each chip region CPR may be square; however, example embodiments are not limited thereto, and the chip regions CPR may be rectangular. A number of chip regions CPR is not limited to those illustrated in FIG. 32, as there may be more or fewer than those illustrated in FIG. 32. Additionally or alternatively, in lieu of or in addition to a flat portion of the wafer WF, the wafer WF may include a notch portion (not illustrated).

Referring to FIG. 32, a semiconductor device 900 may include a chip region CPR and a scribe lane SL surrounding the chip region CPR. Although not illustrated, the semiconductor device 900 may further include a chip guard ring that separates (defines) the chip region CPR and the scribe lane SL. The chip region CPR may correspond to the central region CTREG in FIG. 1 and the scribe lane SL may correspond to the external region EREG in FIG. 1.

Crack detection structures according to some example embodiments may be applied to any electronic devices and systems formed using semiconductor dies. For example, example embodiments may be applied to systems such as one or more of a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IOT) device, an internet of everything (IoE) device, an e-book reader, a virtual reality (VR) device, an augmented reality (AR) device, a robotic device, a drone, an automotive, etc.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

The foregoing is illustrative of some example embodiments and is not to be construed as limiting thereof. Although a few example embodiments have been described, those of ordinary skill in the art will readily appreciate that many modifications are possible in example embodiments without materially departing from the novel teachings and advantages of the example embodiments. Accordingly, all such modifications are intended to be included within the scope of example embodiments as defined in the claims. Furthermore example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
a semiconductor die including a central region in which a semiconductor integrated circuit is arranged and an external region surrounding the central region;
a chip guard ring inside the semiconductor die along an edge of the semiconductor die, the chip guard ring separating the central region and the external region;
a first crack detection structure along an edge of the central region and in a closed curve;
a second crack detection structure along the edge of the central region in a closed curve, the second crack detection structure being spaced apart from the chip guard ring farther than the first crack detection structure; and
a detection controller configured to:
in a first phase, induce an electrical short circuit between the first crack detection structure and the second crack detection structure by applying a first power to the first crack detection structure and by applying a second power greater than the first power to the second crack detection structure;
in a second phase, apply a test input signal to the first crack detection structure; and
determine whether a progressive crack occurs in the central region based on whether a test output signal responding to the test input signal is detected in the second crack detection structure in the second phase.

2. The semiconductor device of claim 1, wherein the detection controller is configured to:
apply a first power supply voltage and a second power supply voltage having a voltage level greater than a voltage level of the first power supply voltage to the first crack detection structure and the second crack detection structure, respectively during a first time interval in the first phase; and
apply at least one of pulse signal or a direct current (DC) voltage to the first crack detection structure as the test input signal during a second time interval in the second phase.

3. The semiconductor device of claim 2, wherein the detection controller is configured to determine that the crack occurs in the central region in response to the pulse signal or the DC voltage being detected in the second crack detection structure.

4. The semiconductor device of claim 3, wherein the detection controller is configured to:
apply a ground voltage and a power supply voltage to the first crack detection structure and the second crack detection structure, respectively, during a first time interval in the first phase; and
apply at least one of a pulse signal or a direct current (DC) voltage to the first crack detection structure as the test input signal during a second time interval in the second phase.

5. The semiconductor device of claim 4, wherein the detection controller is configured to determine that the crack occurs in the central region in response to the pulse signal or the DC voltage being detected in the second crack detection structure.

6. The semiconductor device of claim 1, wherein the detection controller is configured to:
apply the first power supply to the first crack detection structure using a first voltage generator that is in the central region; and
apply the second power supply to the second crack detection structure using a second voltage generator that is in the central region.

7. The semiconductor device of claim 1, wherein the detection controller is configured to:
apply the first power supply provided from an outside to the first crack detection structure by using a first pad that is in the central region; and
apply the second power supply provided from the outside to the second crack detection structure by using a second pad that is in the central region.

8. The semiconductor device of claim 1, wherein the detection controller is configured to:
apply the first power supply to the first crack detection structure by using a voltage generator that is in the central region; and
apply the second power supply provided from an outside to the second crack detection structure by using a pad that is in the central region.

9. The semiconductor device of claim 1, wherein, in response to a crack exists in the chip guard ring, the detection controller is configured to accelerate a progress of the crack by applying the first power and the second power so as to generate an electrical field between the first crack detection structure and the second crack detection structure.

10. The semiconductor device of claim 1, further comprising:
a first switch circuit configured to switch the first power to the first crack detection structure during a first time interval in the first phase and configured to switch the test input signal to the first crack detection structure during a second time interval in the second phase; and
a second switch circuit configured to switch the second power to the second crack detection structure during the first time interval in the first phase and configured to connect the second crack detection structure to the detection controller in the second phase.

11. The semiconductor device of claim 1,
wherein the semiconductor die includes a plurality of conduction layers stacked in a vertical direction,
wherein the first crack detection structure includes a vertical conduction loop extending in the vertical direction through the plurality of conduction layers,
wherein the vertical conduction loop includes:
a plurality of horizontal lines in a respective one of the plurality of conduction layers; and
a plurality of vertical lines connecting each of the plurality of horizontal lines, and
wherein the second crack detection structure includes a plurality of horizontal conduction loops, each of the plurality of horizontal conduction loops being arranged in respective one of the plurality of conduction layers.

12. The semiconductor device of claim 11, further comprising:
a first switch circuit configured to provide the first power to the first crack detection structure during a first time interval in the first phase and configured to provide the test input signal to the first crack detection structure during a second time interval in the second phase; and
a second switch circuit configured to provide the second power to the second crack detection structure during the first time interval in the first phase and configured to connect the second crack detection structure to the detection controller in the second phase,
wherein the detection controller is configured to:
apply a first switching control signal to the first switch; and
apply a second switching control signal and a third switching control signal to the second switch.

13. The semiconductor device of claim 12, wherein, in response to the first switching control signal, the first switch is configured to:
provide the first power to the first crack detection structure during the first time interval in the first phase;
provide the test input signal to the first crack detection structure during the second time interval in the second phase.

14. The semiconductor device of claim 12, wherein, in response to the second switching control signal and the third switching control signal, the second switch circuit is configured to:
provide the second power to the second crack detection structure during the first time interval in the first phase;
connect the second crack detection structure to the detection controller during the second time interval in the second phase.

15. The semiconductor device of claim 12, wherein the second switch circuit comprises:
a first sub switch connected between the detection controller and a first node; and
a plurality of second sub switches commonly connected to the first node and connected to the plurality of horizontal conduction loops, respectively.

16. The semiconductor device of claim 15, wherein, in response to the second switching control signal, the first sub switch is configured to:
provide the second power to the first node in the first phase; and
connect the first node to the detection controller in the second phase.

17. The semiconductor device of claim 15, wherein, in response to the third switching control signal, the plurality of second sub switches are configured to:
provide the plurality of horizontal conduction loops with the second power provided to the first node in the first phase; and
connect at least a portion of the plurality of horizontal conduction loops to the detection controller through the first node and the first sub switch in the second phase.

18. A method of detecting a progressive crack in a semiconductor device, wherein the semiconductor device includes a semiconductor die including a central region in which a semiconductor integrated circuit is arranged, an external region surrounding the central region, and a chip guard ring inside the semiconductor die along an edge of the semiconductor die to separate the central region and the external region, the method comprising:
applying a first power and a second power greater than the first power to a first crack detection structure and a second crack detection structure, respectively, during a first time interval in a first phase, wherein the first crack detection structure is arranged along an edge of the central region as a closed curve, the second crack detection structure is arranged along the edge of the central region as a closed curve and the second crack detection structure is spaced apart from the chip guard ring farther than the first crack detection structure;
applying a test input signal to the first crack detection structure during a second time interval in a second phase; and
determining whether a progressive crack occurs in the central region based on whether a test output signal responding to the test input signal is detected in the second crack detection structure in the second phase.

19. The method of claim 18,
wherein applying the test input signal includes:
applying at least one of a pulse signal or a direct current (DC) voltage to the first crack detection structure as the test input signal during a second time interval in the second phase, and
wherein determining whether the progressive crack occurs includes:
determining that the crack occurs in the central region in response to the pulse signal or the DC voltage being detected in the second crack detection structure.

20. A semiconductor device comprising:
a semiconductor die including a central region in which a semiconductor integrated circuit is arranged and an external region surrounding the central region;
a chip guard ring arranged inside the semiconductor die along an edge of the semiconductor die to separate the central region and the external region;
a crack detection structure arranged along an edge of the central region in a form of a closed curve; and
a detection controller configured to:
induce an electrical short circuit between the crack detection structure and the chip guard ring by applying a power to the crack detection structure during a first time interval in a first phase;
apply a test input signal to the crack detection structure in a second phase; and
determine whether a progressive crack occurs in the central region based on whether a test output signal responding to the test input signal is detected in the crack detection structure in the second phase.
